(19) United States
(12) Patent Application Publication
(10) Pub. No.: US 2025/0044709 A1
(43) Pub. Date: Feb. 6, 2025

(54) METHOD AND APPARATUS TO DETERMINE OVERLAY

(71) Applicant: ASML NETHERLANDS B.V., Veldhoven (NL)

(72) Inventor: Willem Louis VAN MIERLO, Helmond (NL)

(73) Assignee: ASML NETHERLANDS B.V., Veldhoven (NL)

(21) Appl. No.: 18/718,306

(22) PCT Filed: Nov. 22, 2022
(86) PCT No.: PCT/EP2022/082685

§ 371 Date: Jun. 10, 2024

Related U.S. Application Data
(60) Provisional application No. 63/291,759, filed on Dec. 20, 2021.

(51) Int. Cl. G03F 7/00; G06T 7/00

(52) U.S. Cl. CPC G03F 7/70633; G03F 7/70655; G03F 7/706837; G03F 7/706841; G03F 7/706847; G06T 7/0004; G06T 2207/10061; G06T 2207/20056; G06T 2207/30148

(57) ABSTRACT

Systems, methods, and media for determining a processing parameter associated with a lithography process. In some embodiments, image data of features on a substrate may be obtained, and the image data may be analyzed in Fourier space. Based on the analysis, an amplitude and a phase may be determined, and an overlay of the features may be determined based on the amplitude and the phase.

### CROSS-REFERENCE TO RELATED APPLICATIONS

This application claims priority of U.S. application 63/291,759 which was filed on Dec. 20, 2021 and which is incorporated herein in its entirety by reference.

### FIELD

The present description relates to determining a parameter (such as overlay) of a process creating a pattern on a substrate based on an analysis of an image of the patterned substrate in Fourier space.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput defect inspection and metrology of two-dimensional and three-dimensional structures.

### SUMMARY

In an embodiment, there is provided a method, including obtaining image data of features on a substrate; analyzing the image data in Fourier space; determining an amplitude and a phase based on the analysis; and determining an overlay based on the amplitude and the phase.

In an aspect, there is provided a non-transitory computer program product comprising machine-readable instructions for causing a processor system to cause performance of a method described herein. In an aspect, there is provided a computer program product comprising a computer non-transitory readable medium having instructions recorded thereon, the instructions when executed by a computer implementing a method or one or more process steps described herein.

In an aspect, there is provided a metrology apparatus for measuring an object of a patterning process, the metrology apparatus configured to perform a method as described herein.

In an aspect, there is provided an inspection apparatus for inspecting an object of a patterning process, the inspection apparatus being operable to perform a method as described herein.

In an aspect, there is provided a system comprising: a metrology apparatus; and a computer program product as described herein. In an embodiment, the system further comprises a lithographic apparatus comprising a support structure configured to hold a patterning device to modulate a radiation beam and a projection optical system arranged to project the modulated radiation beam onto a radiation-sensitive substrate, wherein the object is the substrate.

In an embodiment, there is provided a system comprising: a hardware processor system; and a non-transitory computer readable storage medium configured to store machine-readable instructions, wherein when executed, the machine-readable instructions cause the hardware processor system to perform a method as described herein.

### BRIEF DESCRIPTION OF THE DRAWINGS

The accompanying drawings, which are incorporated in and constitute a part of the specification, illustrate one or more embodiments and, together with the description, explain these embodiments. Embodiments will now be described, by way of example only, with reference to the accompanying schematic drawings in which corresponding reference symbols indicate corresponding parts, and in which:

FIG. 1 is a schematic diagram of a lithographic projection apparatus, according to an embodiment;

FIG. 2 depicts a schematic overview of a lithographic cell, according to an embodiment;

FIG. 3 depicts a schematic representation of holistic lithography, representing a cooperation between three technologies to optimize semiconductor manufacturing, according to an embodiment;

FIG. 4 schematically depicts an embodiment of a charged particle (e.g., an electron beam) inspection apparatus, according to an embodiment;

FIG. 5 schematically illustrates another embodiment of an inspection apparatus, according to an embodiment;

FIG. 6A depicts an example image of a substrate having features located on a first layer and features located on a second layer, the second layer being formed over the first layer, in accordance with an embodiment;

FIG. 6B depicts a zoomed in portion of the image of FIG. 6A, in accordance with an embodiment;

FIG. 7A is a schematic representation of a portion of an image of a substrate having stacked layers each including one or more features, in accordance with an embodiment;

FIG. 7B is a schematic representation of the portion of the image from FIG. 7A where only a first layer including first features are shown, in accordance with an embodiment;

FIG. 8 corresponds to a method for applying a Fourier transform to a two-dimensional image, in accordance with an embodiment;

FIG. 9 depicts an example amplitude image obtained by applying a Fourier transform to the image of FIG. 6A, in accordance with an embodiment;

FIGS. 10A and 10B depict an example interpolation process to determine a peak's coordinates in Fourier space with sub-pixel accuracy, in accordance with an embodiment;

FIG. 11 depicts an example phase image obtained by apply a Fourier transform to the image of FIG. 6A, in accordance with an embodiment;

FIG. 12 is a schematic representation of a zoomed in portion of the example amplitude image of FIG. 9, in accordance with an embodiment;

FIG. 13 corresponds to a method for determining overlay using a Fourier transform of an image of a patterned device, in accordance with an embodiment;

FIG. 14 is an example graph of a calibration process, in accordance with an embodiment;

FIG. 15 is an image of a phase image of a patterned device including example points used for forming the traces of the example graph of FIG. 14, in accordance with an embodiment; and

FIG. 16 is an example graph of a calibration process including an ideal example calibration factor, in accordance with an embodiment.

FIG. 17 is a block diagram of an example computer system, according to an embodiment.

FIG. 18 is schematic diagram of another lithographic projection apparatus, according to an embodiment.

FIG. 19 is a more detailed view of components of a lithographic projection apparatus (e.g., the lithographic projection apparatus illustrated in FIG. 1 or FIG. 18), according to an embodiment.

FIG. 20 is a detailed view of the source collector module of a lithographic projection apparatus, according to an embodiment.

### DETAILED DESCRIPTION

Electronic devices are constructed of circuits formed on a piece of silicon called a substrate or a wafer. Many circuits may be formed as a repeating pattern of features together on the same piece of silicon, and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

To monitor manufacturing process variation, contours of identical pattern features may be determined based on SEM images of substrate patterns. The contours can be stacked and statistically analyzed to determine the variation of a given feature. Some of the contours are typically outliers, and the stacking and averaging of the contours “hides” these outliers, which may result in reduced accuracy measurement/characterization of certain manufacturing process characteristics, such as critical dimension, edge placement error, or overlay error, among others. The present disclosure describes filtering certain outlier contours before they are stacked and statistically analyzed. Contours may be analyzed and, in some embodiments, a score rates how close to “ideal” the contour is, and the contours with scores below a threshold are filtered and the remaining contours are stacked. The filtering can be performed at multiple levels, such as based on individual points on the contours in a set of inspection contours, or based on overall geometrical shapes of the contours in the set of inspection contours. This may enhance the accuracy of measurement/characterization of these manufacturing process characteristics, thereby enabling more optimal adjustments to be made to the manufacturing process to increase device yield, or may have other advantages.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display (LCD) panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “projection optics,” as used herein, should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting or projecting radiation from the source before the radiation passes the (e.g., semiconductor) patterning device, or optical components for shaping, adjusting or projecting the radiation after the radiation passes the patterning device. The projection optics generally exclude the source and the patterning device.

A (e.g., semiconductor) patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include or specify specific parameters, limits on ranges for parameters, or other information. One or more of the design rule limitations or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. An example of a programmable LCD array is given in U.S. Pat. No. 5,229,872, which is incorporated herein by reference.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer).

As used herein, a “printed pattern” means the physical pattern on a substrate that was etched based on a target pattern. The printed pattern can include, for example, troughs, channels, depressions, edges, or other two and three dimensional features resulting from a lithography process.

As used herein, the term “prediction model”, “process model”, “electronic model”, or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an optical proximity correction (OPC) model (e.g., that can be used to make target patterns and may include sub-resolution resist features (SRAFs), etc.), an etch (or etch bias) model (e.g., that simulates the physical effects of an etching process on a printed wafer pattern), or other models.

As used herein, the term “calibrating” means to modify (e.g., improve or tune) or validate something, such as a model.

A patterning system may be a system comprising any or all of the components described above, plus other components configured to performing any or all of the operations associated with these components. A patterning system may include a lithographic projection apparatus, a scanner, systems configured to apply or remove resist, etching systems, or other systems, for example.

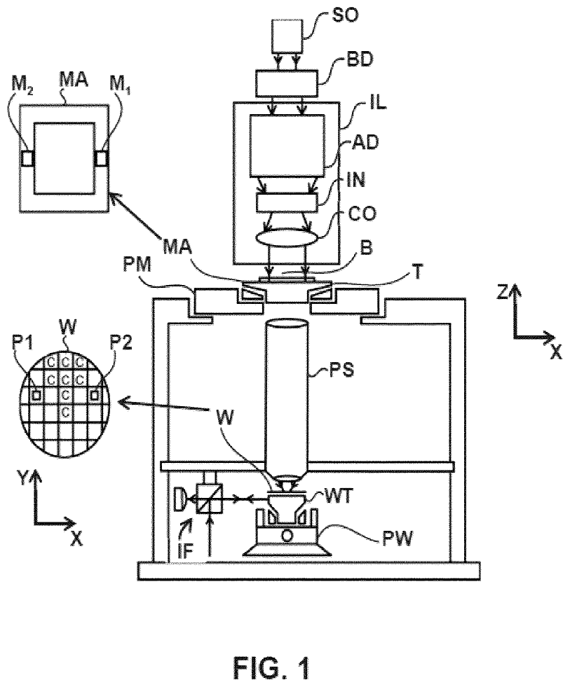

As an introduction, FIG. 1 is a schematic diagram of a lithographic projection apparatus, according to an embodiment. The lithographic projection apparatus can include an illumination system IL, a first object table T, a second object table WT, and a projection system PS. Illumination system IL, can condition a beam B of radiation. In this example, the illumination system also comprises a radiation source SO. First object table (e.g., a patterning device table) T can be provided with a patterning device holder to hold a patterning device MA (e.g., a reticle), and connected to a first positioner to accurately position the patterning device with respect to item PS. Second object table (e.g., a substrate table) WT can be provided with a substrate holder to hold a substrate W (e.g., a resist-coated silicon wafer), and connected to a second positioner to accurately position the substrate with respect to item PS. Projection system (e.g., which includes a lens) PS (e.g., a refractive, catoptric or catadioptric optical system) can image an irradiated portion of the patterning device MA onto a target portion C (e.g., comprising one or more dies) of the substrate W. Patterning device MA and substrate W may be aligned using patterning device alignment marks M1, M2 and substrate alignment marks P1, P2, for example.

As depicted, the apparatus can be of a transmissive type (i.e., has a transmissive patterning device). However, in general, it may also be of a reflective type, for example (with a reflective patterning device). The apparatus may employ a different kind of patterning device for a classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander, or beam delivery system BD (comprising directing mirrors, the beam expander, etc.). for example. The illuminator IL may comprise adjusting means AD for setting the outer or inner radial extent (commonly referred to as c-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus. The radiation beam that it produces may be led into the apparatus (e.g., with the aid of suitable directing mirrors), for example. This latter scenario can be the case when source SO is an excimer laser (e.g., based on KrF, ArF or F2 lasing), for example.

The beam B can subsequently intercept patterning device MA, which is held on a patterning device table T. Having traversed patterning device MA, the beam B can pass through the lens PL, which focuses beam B onto target portion C of substrate W. With the aid of the second positioning means (and interferometric measuring means IF), the substrate table WT can be moved accurately, e.g. to position different target portions C in the path of beam B. Similarly, the first positioning means can be used to accurately position patterning device MA with respect to the path of beam B, e.g., after mechanical retrieval of the patterning device MA from a patterning device library, or during a scan. In general, movement of the tables T, WT can be realized with the aid of a long-stroke module (coarse positioning) and a short-stroke module (fine positioning). However, in the case of a stepper (as opposed to a step-and-scan tool), patterning device table T may be connected to a short stroke actuator, or may be fixed.

The depicted tool can be used in two different modes, step mode and scan mode. In step mode, patterning device table T is kept essentially stationary, and an entire patterning device image is projected in one operation (i.e., a single “flash”) onto a target portion C. Substrate table WT can be shifted in the x or y directions so that a different target portion C can be irradiated by beam B. In scan mode, essentially the same scenario applies, except that a given target portion C is not exposed in a single “flash.” Instead, patterning device table T is movable in a given direction (e.g., the “scan direction”, or the “y” direction) with a speed v, so that projection beam B is caused to scan over a patterning device image. Concurrently, substrate table WT is simultaneously moved in the same or opposite direction at a speed V=Mv, in which M is the magnification of the lens (typically, M=¼ or ⅕). In this manner, a relatively large target portion C can be exposed, without having to compromise on resolution.

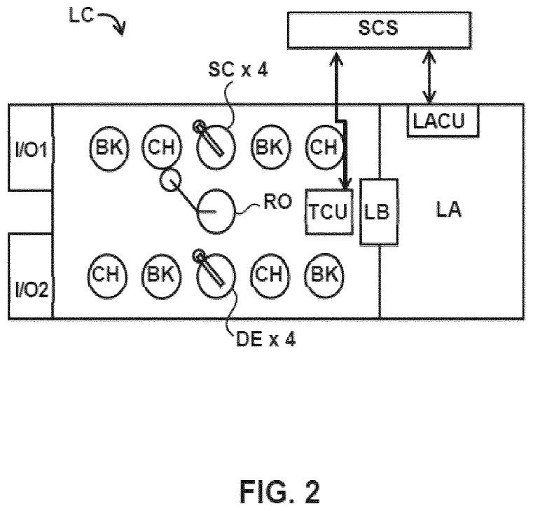

FIG. 2 depicts a schematic overview of a lithographic cell LC. As shown in FIG. 2 the lithographic apparatus LA may form part of lithographic cell LC, also sometimes referred to as a lithocell or (litho)cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W (FIG. 1) exposed by the lithographic apparatus LA to be exposed correctly and consistently, it is desirable to inspect substrates to measure properties of patterned structures, such as feature edge placement, overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W (FIG. 1), and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties using an actual substrate (e.g., a charged particle—SEM—image of a wafer pattern) or an image of an actual substrate, on a latent image (image in a resist layer after the exposure), on a semi-latent image (image in a resist layer after a post-exposure bake step PEB), on a developed resist image (in which the exposed or unexposed parts of the resist have been removed), on an etched image (after a pattern transfer step such as etching), or in other ways.

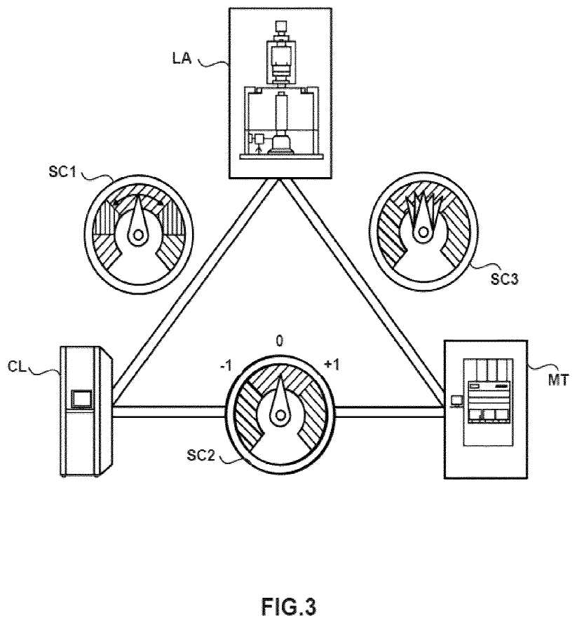

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) a design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

In lithographic processes, it is desirable to make frequent measurements of the structures created, e.g., for process control and verification. Tools to make such measurements include metrology tool (apparatus) MT. Different types of metrology tools MT for making such measurements are known, including scanning electron microscopes (SEM) or various forms of scatterometer metrology tools MT. In some embodiments, metrology tools MT are or include an SEM.

In some embodiments, metrology tools MT are or include a spectroscopic scatterometer, an ellipsometric scatterometer, or other light based tools. A spectroscopic scatterometer may be configured such that the radiation emitted by a radiation source is directed onto target features of a substrate and the reflected or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra. An ellipsometric scatterometer allows for determining parameters of a lithographic process by measuring scattered radiation for each polarization states. Such a metrology tool (MT) emits polarized light (such as linear, circular, or elliptic) by using, for example, appropriate polarization filters in the illumination section of the metrology apparatus. A source suitable for the metrology apparatus may provide polarized radiation as well.

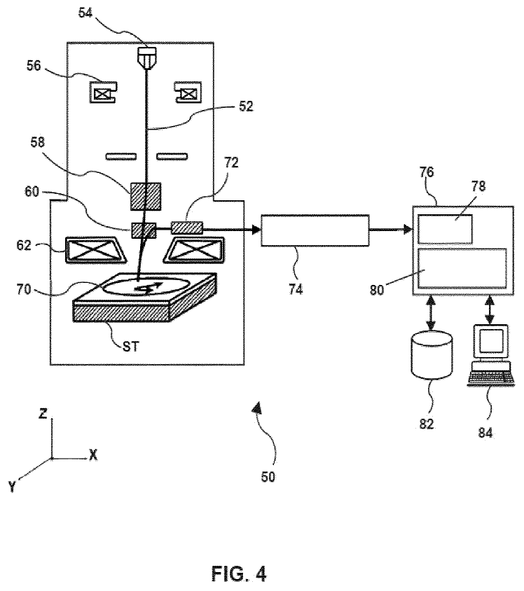

As described above, fabricated devices (e.g., patterned substrates) may be inspected at various points during manufacturing. FIG. 4 schematically depicts a generalized embodiment of an charged particle (electron beam) inspection apparatus 50. In some embodiments, inspection apparatus 50 may be an electron beam or other charged particle inspection apparatus (e.g., the same as or similar to a scanning electron microscope (SEM)) that yields an image of a structure (e.g., some or all the structure of a device, such as an integrated circuit) exposed or transferred on a substrate. A primary electron beam 52 emitted from an electron source 54 is converged by condenser lens 56 and then passes through a beam deflector 58, an E×B deflector 60, and an objective lens 62 to irradiate a substrate 70 on a substrate table ST at a focus.

When the substrate 70 is irradiated with electron beam 52, secondary electrons are generated from the substrate 70. The secondary electrons are deflected by the E×B deflector 60 and detected by a secondary electron detector 72. A two-dimensional electron beam image can be obtained by detecting the electrons generated from the sample in synchronization with, e.g., two dimensional scanning of the electron beam by beam deflector 58 or with repetitive scanning of electron beam 52 by beam deflector 58 in an X or Y direction, together with continuous movement of the substrate 70 by the substrate table ST in the other of the X or Y direction. Thus, in some embodiments, the electron beam inspection apparatus has a field of view for the electron beam defined by the angular range into which the electron beam can be provided by the electron beam inspection apparatus (e.g., the angular range through which the deflector 60 can provide the electron beam 52). Thus, the spatial extent of the field of the view is the spatial extent to which the angular range of the electron beam can impinge on a surface (wherein the surface can be stationary or can move with respect to the field).

As shown in FIG. 4, a signal detected by secondary electron detector 72 may be converted to a digital signal by an analog/digital (A/D) converter 74, and the digital signal may be sent to an image processing system 76. In some embodiments, the image processing system 76 may have memory 78 to store all or part of digital images for processing by a processing unit 80. The processing unit 80 (e.g., specially designed hardware or a combination of hardware and software or a computer readable medium comprising software) is configured to convert or process the digital images into datasets representative of the digital images. In some embodiments, the processing unit 80 is configured or programmed to cause execution of an operation (e.g., SEM inspection) described herein. Further, image processing system 76 may have a storage medium 82 configured to store the digital images and corresponding datasets in a reference database. A display device 84 may be connected with the image processing system 76, so that an operator can conduct necessary operation of the equipment with the help of a graphical user interface.

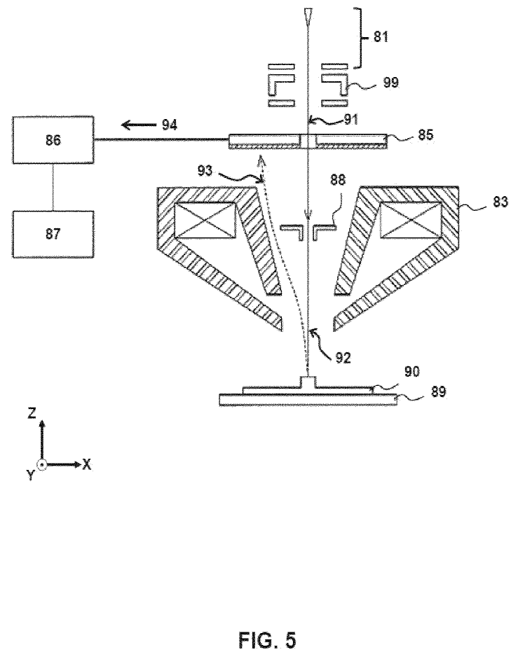

FIG. 5 schematically illustrates another embodiment of a charged particle inspection apparatus. The apparatus is used to inspect a sample 90 (such as a patterned substrate) on a sample stage 89 and comprises a charged particle beam generator 81, a condenser lens module 99, a probe forming objective lens module 83, a charged particle beam deflection module 88, a secondary charged particle detector module 85, an image forming module 86, or other components. The charged particle beam generator 81 generates a primary charged particle beam 91. The condenser lens module 99 condenses the generated primary charged particle beam 91. The probe forming objective lens module 83 focuses the condensed primary charged particle beam into a charged particle beam probe 92. The charged particle beam deflection module 88 scans the formed charged particle beam probe 92 across the surface of an area of interest on the sample 90 secured on the sample stage 89. In some embodiments, the charged particle beam generator 81, the condenser lens module 83, and the probe forming objective lens module 83, or their equivalent designs, alternatives or any combination thereof, together form a charged particle beam probe generator which generates the scanning charged particle beam probe 92.

The secondary charged particle detector module 85 detects secondary charged particles 93 emitted from the sample surface (maybe also along with other reflected or scattered charged particles from the sample surface) upon being bombarded by the charged particle beam probe 92 to generate a secondary charged particle detection signal 94. The image forming module 86 (e.g., a computing device) is coupled with the secondary charged particle detector module 85 to receive the secondary charged particle detection signal 94 from the secondary charged particle detector module 85 and accordingly form at least one scanned image. In some embodiments, the secondary charged particle detector module 85 and image forming module 86, or their equivalent designs, alternatives or any combination thereof, together form an image forming apparatus which forms a scanned image from detected secondary charged particles emitted from sample 90 being bombarded by the charged particle beam probe 92.

In some embodiments, a monitoring module 87 is coupled to the image forming module 86 of the image forming apparatus to monitor, control, etc. the patterning process or derive a parameter for patterning process design, control, monitoring, etc. using the scanned image of the sample 90 received from image forming module 86. In some embodiments, the monitoring module 87 is configured or programmed to cause execution of an operation described herein. In some embodiments, the monitoring module 87 comprises a computing device. In some embodiments, the monitoring module 87 comprises a computer program configured to provide functionality described herein. In some embodiments, a probe spot size of the electron beam in the system of FIG. 3 is significantly larger compared to, e.g., a CD, such that the probe spot is large enough so that the inspection speed can be fast. However, the resolution may be lower because of the large probe spot.

As described above, it may be desirable to use one or more tools to produce results that, for example, can be used to design, control, monitor, etc. a patterning process. One or more tools used in computationally controlling, designing, etc. one or more aspects of the patterning process, such as the pattern design for a patterning device (including, for example, adding sub-resolution assist features or optical proximity corrections), the illumination for the patterning device, etc., may be provided. Accordingly, in a system for computationally controlling, designing, etc. a manufacturing process involving patterning, the manufacturing system components or processes can be described by various functional modules or models. In some embodiments, one or more electronic (e.g., mathematical, parameterized, etc.) models may be provided that describe one or more steps or apparatuses of the patterning process. In some embodiments, a simulation of the patterning process can be performed using one or more electronic models to simulate how the patterning process forms a patterned substrate using a design pattern provided by a patterning device.

Images, from, e.g., the system of FIG. 4 or FIG. 5, may be processed to extract dimensions, shapes, contours, or other information that describe the edges of objects, representing semiconductor device structures, in the image. The shapes, contours, or other information may be quantified via metrics, such as edge placement error (EPE), CD, etc. at user-defined cut-lines or in other locations. These shapes, contours, or other information may be used to optimize a patterning process, for example.

In some embodiments, optimization of a patterning process may be represented as a cost function. The optimization process may comprise finding a set of parameters (design variables, process variables, etc.) of the patterning process that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design or process variables of the patterning process can be confined to finite ranges or be interdependent due to practicalities of implementations of the system or method. In the case of a lithographic projection apparatus, the constraints are often associated with physical properties and characteristics of the hardware such as tunable ranges, or patterning device manufacturability design rules. The evaluation points can include physical points in an image of a substrate, as well as non-physical characteristics such as one or more etching parameters, dose and focus, etc., for example.

In an etching system, as an example, a cost function (CF) may be expressed as

$$C F ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} )$$

where (z₁, z₂, . . . , z_{N}) are N design variables or values thereof, and ƒₚ(z₁, z₂, . . . z_{N}) can be a function of the design variables (z₁, z₂, . . . , z_{N}) such as a difference between an actual value and an intended value of a characteristic for a set of values of the design variables of (z₁, z₂, . . . , z_{N}). In some embodiments, wₚ is a weight constant associated with ƒₚ(z₁, z₂, . . . , z_{N}). For example, the characteristic may be a position of an edge of a pattern (e.g., or multiple points on an edge that form a contour), measured at a given point on the edge. Different ƒₚ (z₁, z₂, . . . , z_{N}) may have different weight wₚ. For example, if a particular edge has a narrow range of permitted positions, the weight wₚ for the ƒₚ(z₁, z₂, . . . , z_{N}) representing the difference between the actual position and the intended position of the edge may be given a higher value. ƒₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in the equation above and CF(z₁, z₂, . . . , z_{N}) can be in any other suitable form.

The cost function may represent any one or more suitable characteristics of a patterning system, a patterning process, lithographic apparatus, lithography process, or the substrate, for instance, focus, CD, image shift, image distortion, image rotation, stochastic variation, throughput, local CD variation, process window, an interlayer characteristic, or a combination thereof. In some embodiments, the cost function may include a function that represents one or more characteristics of a resist image. For example, ƒₚ(z₁, z₂, . . . , z_{N}) can be simply a distance between a point in the resist image to an intended position of that point (i.e., edge placement error EPEₚ(z₁, z₂, . . . , z_{N}) after etching, for example, or some other process. The parameters (e.g., design variables) can include any adjustable parameter such as an adjustable parameter of the etching system, the source, the patterning device, the projection optics, dose, focus, etc.

The parameters (e.g., design variables) may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. Constraints should not be interpreted as a necessity.

Contours of pattern features are often determined based on images of substrate patterns. These contours are used to determine various key performance indicators (KPI), which are in turn used to monitor semiconductor manufacturing process variation. As one example, edge placement error (EPE) has become a common KPI used for monitoring process variation. EPE includes contributions from imaging (e.g., critical dimension (CD) and pattern placement variations) and overlay.

Contours are stacked and analyzed (e.g., overlay) to determine the variation in a given feature. However, some of the contours may be outliers, and the stacking and averaging of the contours “hides” these outliers. For example, the contours may have varying quality (e.g., images may not provide clean, clear, views of edges of features used to determine the contours, and instead may be pixelated, blurry, etc.) or confidence levels (e.g., it may be unclear from a lower quality image exactly where a contour lies in that image, or a particular manufacturing process may have produced an unusual result). Outliers may be caused, for example, by process variation or tool condition drift, because of the intrinsic differences of a pattern design (some patterns are more challenging for imaging, analysis, or other extraction tasks), or for other reasons. If these outlier contours go into a stack and an analysis is performed based on them, the outlier contours may impact any determinations drawn from that stack. Using EPE as an example, an EPE calculation based on a stack that includes outlier contours may cause errant (or at least less accurate) EPE determinations, and unnecessary manufacturing process adjustments to certain manufacturing parameters, when the “budget” for such adjustments may have been best used on other manufacturing parameters.

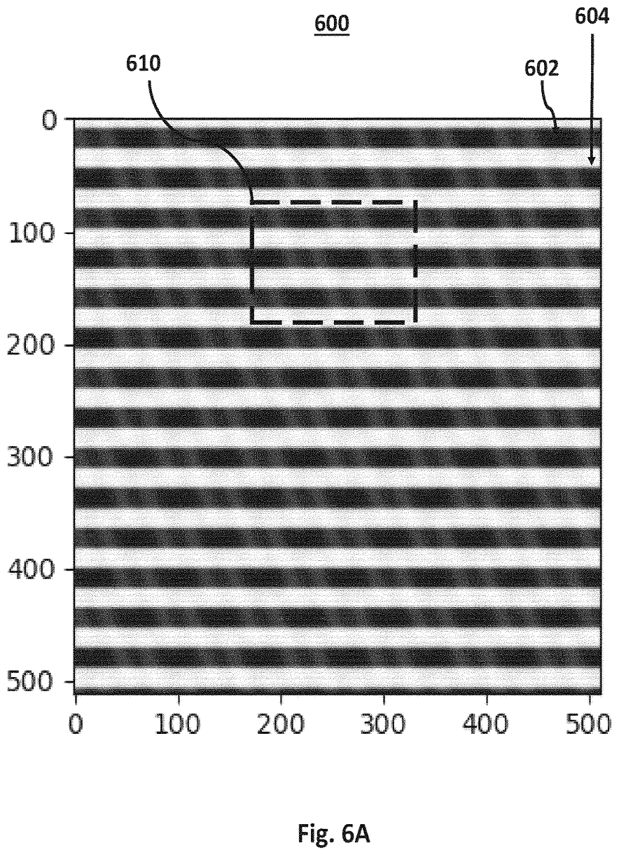

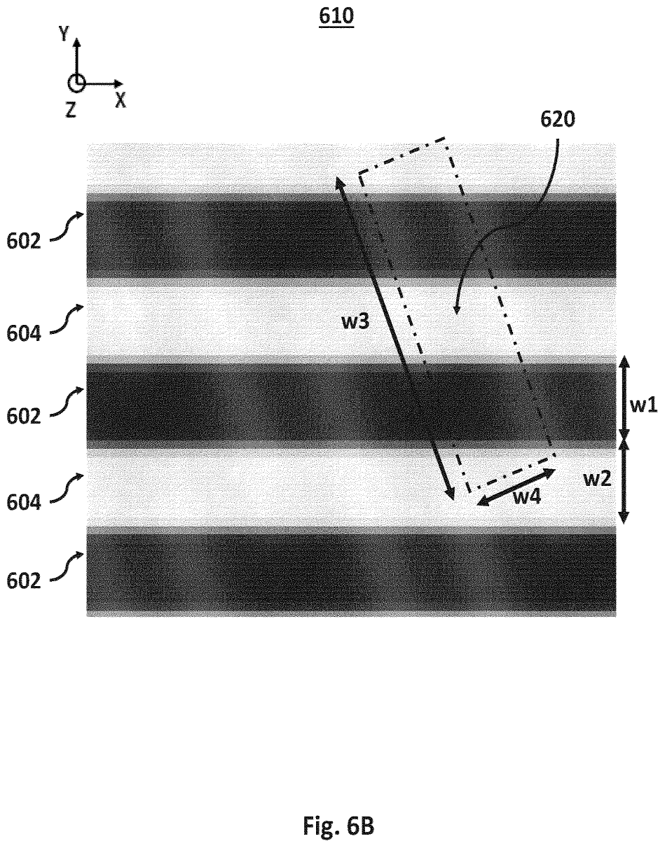

FIG. 6A depicts an example image of a substrate having features located on a first layer and features located on a second layer, the second layer being formed over the first layer, in accordance with an embodiment. As seen in FIG. 6A, image 600 depicts a patterned substrate. For example, a substrate may be patterned using a lithographic apparatus, such as those described with respect to FIG. 1, 18, or 19. In some embodiments, the substrate depicted by image 600 may be a stacked image including two or more layers stacked on top of one another. Each layer may include features formed via a patterning process. In some embodiments, the features may be the same or similar in size, shape, orientation, or other aspects, however they may also differ slightly or substantially in one or more of the aforementioned aspects.

In some embodiments, features formed on a first layer of the substrate may be buried under substantially deep under one or more additional layers. For example, a patterned substrate may have a first layer including first features and a second layer including second features. A height of the second layer, which may reside on the first layer (which may reside on the substrate) may be 100 nm or more, 200 nm or more, 300 nm or more, 400 nm or more, 500 nm or more, or other heights.

In some embodiments, patterning parameters, such as overlay, between features of stacked layers may be determined by analyzing a scanning electron microscope (SEM) image of the patterned device including the stacked layers (e.g., the stacked layers being formed on a substrate via a lithographic patterning process). Some techniques to determine patterning parameters, such as overlay, include direct contouring, cross-correlation to a reference feature, or other techniques employed using metrology systems and metrology techniques described herein. However, the current techniques can produce inaccurate results when the features included in the stacked layers partially overlap, or when the intensity of one of the features is much greater than the intensity of another feature. In the latter case, for example, this can be particularly prevalent when the “lower” layer's features are buried underneath an “upper” layer's features. In such cases, the intensity of the upper layer's features will be much more intense than the that of the lower layer's features.

As an example, with reference to FIG. 6A, image 600 may depict an SEM image of a device patterned using a patterning process via a lithographic apparatus, such as those described herein. Image 600 depicts an image taken from “above” (e.g., looking down on a top surface of a device). From this view, first features 602 may be visible. First features 602 may be a horizontal grating. For example, the pattern of first feature 602 and features 604 between consecutive instances of first features 602 may be represented using a two-dimensional sinusoidal function.

In image 600, first features 602 may be formed on an upper layer of a patterned device. During a patterning process, a lithographic apparatus may form layers on a substrate, where some or all of the layers may include features formed by the patterning process. If the height of one layer (or layers) formed above another layer is large enough (e.g., greater than 300 nm, greater than 400 nm, greater than 500 nm, or other heights), then an intensity, in image 600, of the features formed on the upper layer may be greater than an intensity of the features formed on a lower layer. In some cases, due to the intensity of the features formed on the upper layer, a portion of the image signal (e.g., forming image 600) corresponding to the features on the upper layer may overshadow a portion of the image signal corresponding to the features on the lower layer. As a result, the features on the upper layer may be easily viewable while the features on the lower layer may be completely or partially hidden.

Portion 610 may represent an example region of image 600. For instance, in some cases the features on the upper layer and the lower layer may be periodic within a unit cell (with each set of features having the same or different periods). Portion 610 may, thus, depict a unit cell where the features on the upper layer and/or features on the lower layer may be symmetrically disposed. As seen in FIG. 6B, a zoomed-in version of portion 610 is depicted including features 602, having a width w1 along the y-axis. Between pairs of feature 602 may be a feature 604, having a width w2. In some cases, w1=w2, however, alternatively, w1≠w2. Furthermore, in some cases, w1 and/or w2 may vary along the X and/or Y axes.

In FIG. 6B, an instance of a feature 620 formed on a lower layer (e.g., a layer formed closer to an upper surface of the substrate than a layer with which features 602 are formed) may be partially visible. As seen from the dashed border of feature 620, feature 620 may be rectangular in shape, having a first side length w3 and a second side length w4, where w3>w4. However, persons of ordinary skill in the art will recognize that other shapes, and sizes of those shapes may be used, and the aforementioned is merely exemplary. In addition to being a different shape and size of features 602, features 620 may also be oriented differently. For example, with respect to an orientation of features 602 (e.g., uniform along the x-axis), features 620 may be rotated by an angle θ.

In some embodiments, there can be a relative shift between features 602 and features 620. The relative shift may be from their expected position due to their separate transfer onto the substrate so as to have an error in overlay. In this example, features 602 is located in a higher (e.g., “upper”) layer on a substrate than features 620 (located on a lower layer). Thus, in some embodiments, features 620 can be produced in a first lower layer in a first execution of a patterning process and features 620 can be produced in a second higher layer than the first lower layer in a second execution of the patterning process. In some cases, however, features 602 and 620 may be formed within a same layer.

Significantly, the unit cell has, or is capable of having, a geometric symmetry with respect to an axis or point. For example, FIG. 6B may have reflection symmetry with respect to an axis and/or point/rotational symmetry with respect to a point. In some embodiments, the unit cell has a geometric symmetry for a certain feature (such as overlay). In some cases, the unit cell may have zero overlay when it is geometrically symmetric. However, instead, the unit cell can have zero overlay for a certain geometric asymmetry. Appropriate offsets and calculations would then be used to account for the unit cell having a zero overlay when it has a certain geometric asymmetry. The unit cell should be capable of change in symmetry (e.g., become asymmetry, or become further asymmetric, or become symmetric from an asymmetric situation) depending on the certain feature value.

As an example, an error in overlay with respect to the unit cell where the features on the upper layer are shifted in the X-direction with respect to the features on the lower layer may result in an error in the overlay in the X-direction; that is, an X direction overlay error. Of course, features on the lower layer could be shifted relative to the features on the upper layer or both could be shifted relative to each other. In any event, the result is an X direction overlay error. However, as should be appreciated from this unit cell arrangement, a purely relative shift in the Y-direction between the features on the upper layer and the features on the lower layer would not change the geometric symmetry of this unit cell. But, with an appropriate geometric arrangement, overlay in two directions or between different combinations of parts of the unit cell can change symmetry and could also be determined.

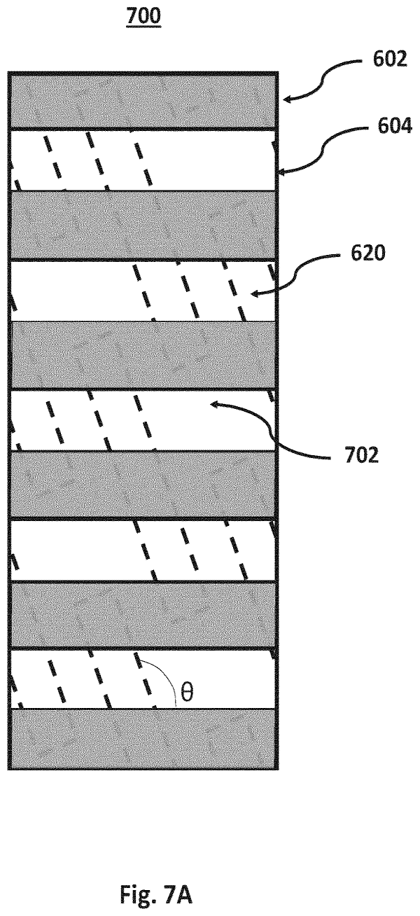

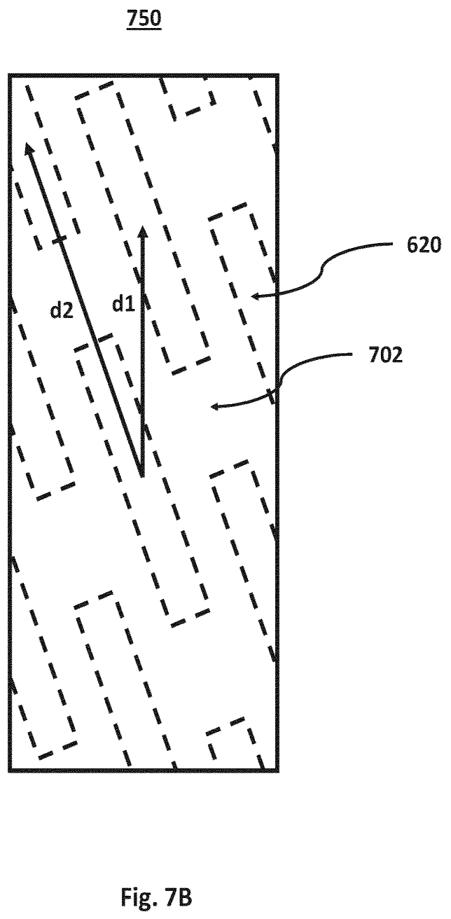

FIG. 7A is a schematic representation of a portion of an image of a substrate having stacked layers each including one or more features, in accordance with an embodiment. FIG. 7B is a schematic representation of the portion of the image from FIG. 7A where only a first layer including first features are shown, in accordance with an embodiment. As seen in FIG. 7A, an image 700 of a portion of a substrate having stacked layers is depicted. The substrate may be substantially similar to the substrate described above with reference to FIG. 6A. Image 700 includes first features 602, which may form a series of parallel lines along the y-axis. First features 602 may be separated by a feature 604. In some embodiments, feature 604 may be an open space however, alternatively, feature 604 may be formed of the upper layer.

Also seen within image 700 may be features 620 located on a lower layer of the stacked layers. Similar to that of FIGS. 6A and 6B, features 620 may be rectangular in shape and may be rotated by an angle θ with respect to features 602 on the upper layer of the stacked layers.

For simplicity, image 750 of FIG. 7B depicts an example of image 700 of FIG. 7A where the features on the upper layer (e.g., features 602) are not present. For instance, this may refer to an image of the substrate prior to the patterning process forming the upper layer on the lower layer. In image 750, features 620 are illustrated, where space 702 is formed between each instance of features 620. In the scenario where features 620 are symmetric about an axis (e.g., an axis rotated by an angle θ), features 620 may have a distance d2 between the centers of consecutive instances of those features. Furthermore, a vector extending from a center of a feature to a center of an adjacent feature (e.g., directly above that feature along the y-axis) may have a distance d1 therebetween.

Depending on the height of the lower layer, upper layer, any intermediary layers, or a combination thereof, the clarity of the features located on the lower layer(s) in the captured image (e.g., image 600) may be too weak to accurately measure one or more process parameters. For instance, the incident beam's particles may be scattered in the upper layer or layers, thereby effecting the resolving power of the incident beam when it reaches the lower layer. Thus, the signal-to-noise ratio (SNR) can be very low for the lower layer. It is also possible that the incident particles of the metrology beam may not be able to penetrate the lower layers, and thus they may not be reflected back to an image detector for reconstructing the image. As a result, defects and/or other aberrations may go undetected, impacting product performance. For example, features 620 may be difficult to detect within image 600, as features 620 may be on a layer located beneath a layer including features 602, 604. The detection difficult may manifest when using image processing techniques to identify physical characteristics of patterned features (e.g., detecting an edge representing a feature's edge, detecting a centroid of a feature, etc.). Due to the low signal to noise ratio (SNR) in the image signal for the regions where the buried features are expected to be, various feature detectors (e.g., edge detectors, Sobel filters, etc.) may not be able to determine those features presence within the captured image.

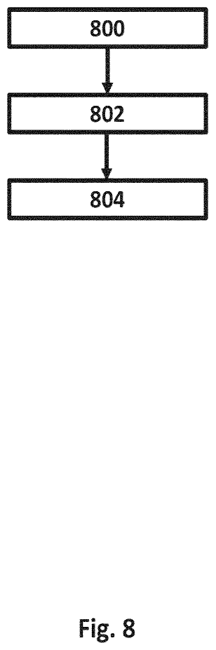

FIG. 8 corresponds to a method for applying a Fourier transform to a two-dimensional image, in accordance with an embodiment. In FIG. 8, at 800, image data comprising an image of a patterned substrate may be obtained. For example, the image data may be captured using a metrology system, such as those described herein with respect to FIGS. 3-5. In some cases, the image data may be SEM image data, where the SEM image data includes an SEM image of the patterned device. As an example image 600 of FIG. 6A may be an SEM image. In some embodiments, the image data may be captured and stored in memory and retrieved for later processing.

At 802, a two-dimension (2D) Fourier transform, which may also be referred to herein interchangeably as a 2D Fast Fourier Transform (FTT) or FTT, for simplicity, may be applied to the image data. The 2D FFT may transform a function in the 2D image plane (e.g., x-y plane) to a function in the 2D frequency plane. For instance, consider the 2D function, ƒ(x, y). The 2D FFT of this function, F(u, v), is represented by Equation (1):

$$F ( u , v ) = \int {\int }_{- ∞}^{∞} f ( x , y ) {e}^{- 2 π i ( ux + vy )} dx dy , \qquad ( 1 )$$

where u and v are spatial frequencies.

The Fourier transform transforms a function into a composition of basis functions. In particular, for the image analysis example described herein (e.g., a metrology process), the Fourier transform transforms an image taken in image space into a composition of basis functions. For example, Equations (2) and (3) represent the Fourier transform of two different 2D sinusoidal functions:

$$sin ( 2 π α x + 2 π β y ) FFT \frac{1}{2 i} ( δ ( u - α , v - β ) - δ ( u + α , v + β ) ) \qquad ( 2 )$$

$$cos ( 2 π α x + 2 π β y ) FFT \frac{1}{2} ( δ ( u - α , v - β ) + δ ( u + α , v + β ) ) . \qquad ( 3 )$$

In terms of the 2D image (e.g., image 600), the process of applying the Fourier transform to the image includes processing the pixel values of each pixel forming the image. For example, image 600 may be an n×m pixels image, and therefore each pixel (n, m) has a value Iₙₘ representing an intensity of light incident on that pixel via the metrology process. The 2D FFT operates in two-steps:
(1) A 1D FFT is performed along each column of pixels of the image; and
(2) A 1D FFT is performed along each row of pixels in the image.

The resulting image may be a 2D image of Fourier coefficients, where there are n×m Fourier coefficients. Lower frequency coefficients are located towards the corners of the image, while higher frequency coefficients are located closer towards the center of the image. In some cases, the frequencies may be shifted such that the lower frequency coefficients towards the center and higher frequency coefficients towards the corners.

By applying the 2D FFT, an amplitude spectrum and a phase spectrum in Fourier space can be generated which together represent the image in image space. The amplitude image, representing the amplitude spectrum, can be computed by calculating, for each frequency of the function in image space, an amplitude.

As an example, (for simplicity, in 1-dimension), applying the Fourier transform to the function ƒ(x)=A cos(nx+φ) may produce the frequency spectrum of the function ƒ(u)=A/2 exp(−i φ) for u=±n/2π. Thus, the amplitude image may be computed by plotting the amplitude, e.g., a magnitude, of each frequency. By doing this, the original signal in spatial space can be represented by a combination of sinusoidal functions with a set of frequencies. The phase image may be generated by computing a phase shift between signals with different frequencies.

Thus, for a 2D function ƒ(x, y) in image space, a 2D FFT function F(u, v), where u and v are spatial frequencies, is computed using Equation (1). In other words, the 2D function ƒ(x, y) can be represented as a linear combination of harmonic functions.

The 2D FTT function F(u, v) is a complex function that includes a real and imaginary portion. The amplitude spectrum may be generated by computing a magnitude of each vector k=u u+v\hat{v}, where |k|=|F(u, v)|, and F(u, v)=Re(F(u, v))+Im(F(u, v)). The phase spectrum may be generating by computing an angle φ for each frequency u, v, where the angle

$$φ = {tan}^{- 1} ( \frac{Im ( F ( u , v ) )}{Re ( F ( u , v ) )} ) .$$

At 804, a first plot of the amplitude spectrum and a second plot of the phase spectrum may be generated. In some embodiments, the first plot and the second plot, or data representing the first plot, the second plot, or the first plot and the second plot, may be stored within memory, (e.g., memory 1706). In some embodiments, the first plot and/or the second plot may be rendered within a user interface displayed on a display device. The first plot of the amplitude spectrum may be referred to herein interchangeably as an “amplitude image,” and the second plot of the phase spectrum may be referred to herein interchangeably as a “phase image.” In some embodiments, the phase image and the amplitude image are generated in parallel, however they may be generated sequentially alternatively.

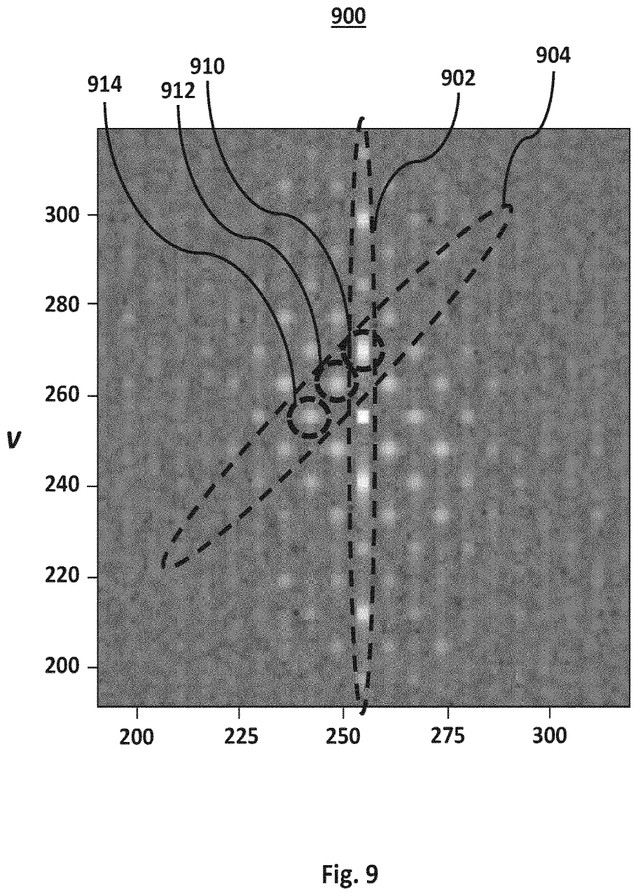

FIG. 9 depicts an example amplitude image obtained by applying a Fourier transform to the image of FIG. 6A, in accordance with an embodiment. Amplitude image 900 includes a first set of peaks 902 and a second set of peaks 904. Each peak within first set of peaks 902 may represent the Fourier transform of the image signal of the image relating to the features on the “upper” layer. For example, peak 910 is a peak from first set of peaks 902, relating to the features on the “upper” layer (e.g., the horizontal gratings). On the other hand, each peak within second set of peaks 904 may represent (a portion of) the Fourier transform of (a portion of) the image signal of the image relating to the features on the “lower” layer. For example, peaks 912 and 914 are peaks from second set of peaks 904, relating to the features on the “lower” layer (e.g., the rectangular features). Each peak displayed within amplitude image 900 may be associated with a particular location in Fourier space (e.g., defined by a u coordinate and a v coordinate). Furthermore, each point (e.g., {u, v}) in Fourier space may correspond to a sinusoidal signal in image space.

A technical improvement of performing the Fourier transform to the image of the patterned substrate in image space is that even if the buried features produce a very weak image signal to contribute to the overall final output image, those weak signals still have a defined representation in Fourier space that can be isolated and analyzed.

Based on the amplitude image, a determination can be made as to which peaks are associated with which features. In some embodiments, one or more optimization algorithms may be used to fit two sets of peaks to the peaks in the amplitude image. In some embodiments, peak position and amplitude are fitted using a non-linear least squares optimization routine where the peak shape is fit using a Gaussian function on a constant background representing the noise level, though the peak shape may also be described by the Fourier transform of the windowing function applied to the image in image space. The two sets of peaks may correspond to peaks associated with features on the “upper” layer (e.g., features 602) and peaks associated with features on the “lower” layer (e.g., features 620). Based on the fit peaks, a peak position of each peak in Fourier space may be obtained with sub-pixel accuracy.

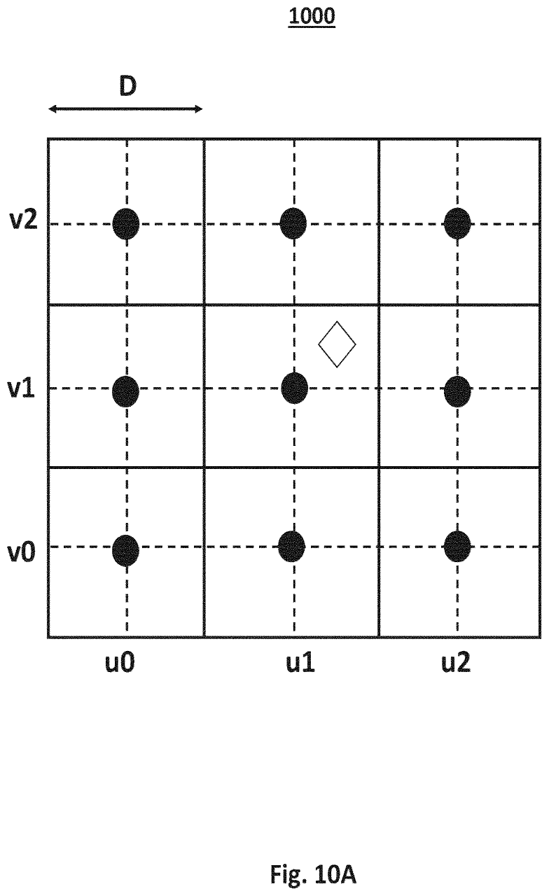

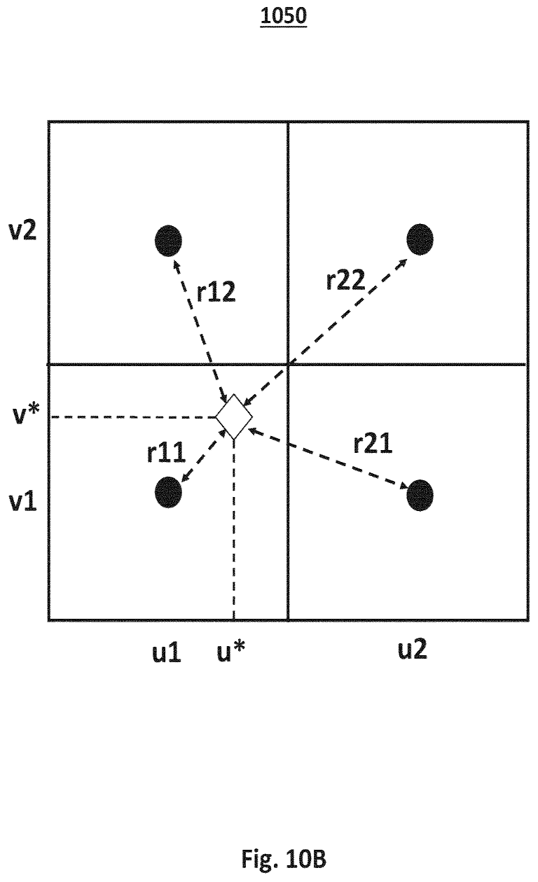

Fitting peaks may enable sub-pixel accuracy to be obtained for each peak, which allows for sub-pixel phase resolution when determining the phase associated with a given peak. The greater the accuracy in determining the phase results in greater precision when determining patterning process metrics, such as overlay. As an example, with reference to FIG. 10A, an amplitude image 1000 illustrates a 3×3 pixel array. Each pixel in the pixel array may have a height and width D, however the height and width can be different, and are set equal to each other for simplicity.

In amplitude image 1000, each circle represent a center of a given pixel in Fourier space. For example, the nine pixels can be labeled via their center coordinates (e.g., Pixel Centers: {uᵢ, vⱼ}, where i=0, 1, 2, and j=0, 1, 2). If the peaks in the amplitude image are located at one of the center positions of one of the pixels, then determining the phase for that corresponding pixel can be computed via

$$φ = {tan}^{- 1} ( \frac{Im ( F ( u , v ) )}{Re ( F ( u , v ) )} ) ,$$

where F(u, v)=Re(F(u, v))+Im(F(u, v)). However, if a peak is not located at a center of a pixel, then an interpolation process can be used to interpolate a sub-pixel position of the peak in the amplitude image and, based on the corresponding sub-pixel position, determine the phase φ for that sub-pixel position. For example, the diamond in amplitude image 1000 may represent a peak, such as one of peaks 912 or 914. As seen from FIG. 10A, the diamond is not located at a center of a pixel. Therefore, its coordinates {u, v} may be determined by interpolating its location with respect to the centers of its surrounding pixels.

As an example, with reference to FIG. 10B, amplitude image 1050 represents a sub-section of the pixel array seen in FIG. 10A. Amplitude image 1050, for example, depicts the diamond representing a peak produced via the Fourier transform of the image signal (e.g., one of peaks 910, 912, 914 of FIG. 9). To determine the coordinates of the diamond, an interpolation process is performed to compute a relative location of the diamond with respect to the centers of the surrounding pixels. For example, vectors r11, r12, r21, and r22 may be computed. Vector r11 represents a distance from center {u1, v1} to the diamond, vector r12 represents a distance from center {u1, v2} to the diamond, vector r21 represents a distance from center {u2, v1} to the diamond, and vector r22 represents a distance from center {u2, v2} to the diamond. These vectors (e.g., vectors r11-r22) and the centers of each pixel may be used to resolve a coordinate location of the diamond {u*, v*}. The coordinate location {u*, v*} may then be used to compute the phase for that peak (e.g.,

$$( e . g . , φ ( {u}^{*} , {v}^{*} ) = {tan}^{- 1} ( \frac{Im ( F ( u * , v \text{*)} )}{Re ( F ( u * , v \text{*)} )} ) .$$

Using the interpolation process described herein enables more accurate overlay (or other critical feature metric) determination, which can improve the lithographic process by determining, with greater precision, an extent of the overlay of a patterned device. In particular, when the patterned device includes stacked layers, where the lower layer is buried beneath one or more other layers (e.g., a distance between the lower layer and an upper surface of the patterned device is greater than d), the techniques described herein allow for precise computation of various patterning metrics, such as overlay, when other image processing techniques may be unable to even detect the lower layer's features.

In some embodiments, each peak, and each peak's corresponding peak position in Fourier space, may be classified into one of two sets of peaks: a first set of peaks (e.g., first set of peaks 902) associated with the features formed on the upper layer of the imaged device (e.g., the substrate including the stacked layers) or a second set of peaks (e.g., second set of peaks 904) associated with the features formed on the lower layer of the imaged device. The peak positions may then be used to compute a phase from the phase image.

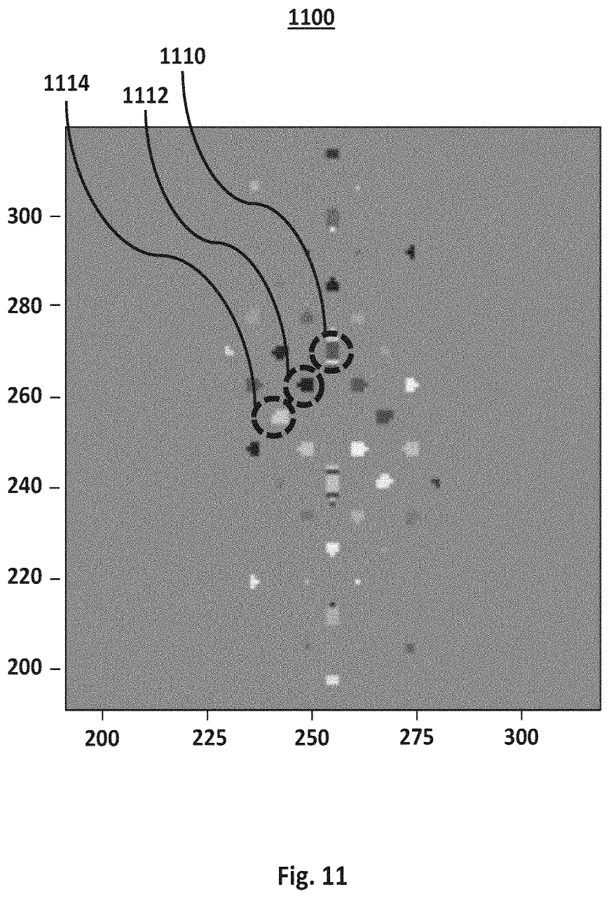

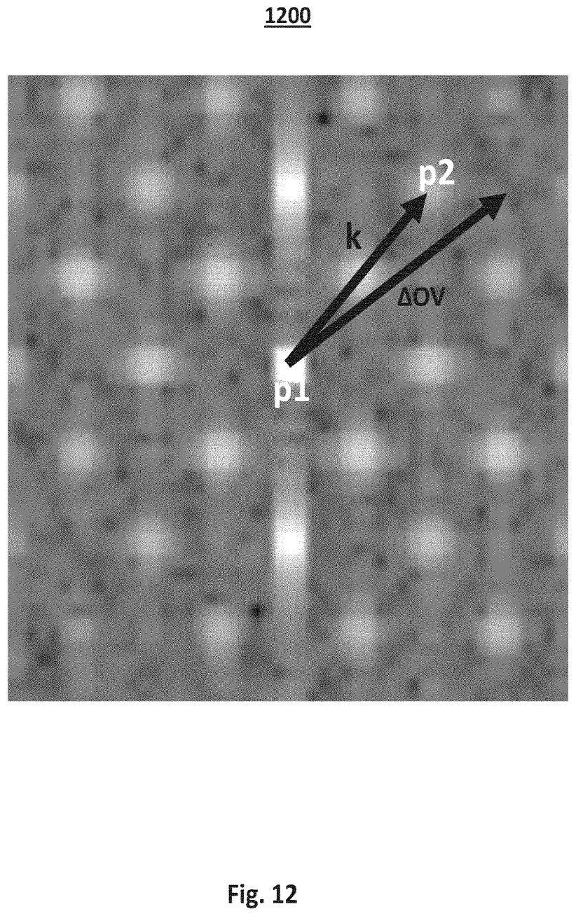

FIG. 11 is a schematic representation a phase image 1100. Phase image 1100 depicts a phase associated with each peak from amplitude image 900. For example, point 1110 corresponds to peak 910, point 1112 corresponds to peak 912, and point 1114 corresponds to peak 914. The phase represents a shift in image space of a sinusoidal signal with a propagation vector, k, extending from a center (e.g., the origin in Fourier space) of a feature to a point of interest. For example, with reference to FIG. 12, amplitude image 1200 depicts a vector k extending from an origin in Fourier space, to a point of interest in Fourier space. The magnitude of the vector k relates to the unit cell dimensions of the feature, as seen by Equation (4):

$$\vert k \vert = \frac{1}{{P}_{spot}} , \qquad ( 4 )$$

where Pₛₚₒₜ represents the pitch corresponding to the point of interest.

The phase is a shift of the sinusoidal signal in image space associated with vector k. The phase φ can be computed for a given u and v by

$$φ = {tan}^{- 1} ( \frac{Im ( F ( u , v ) )}{Re ( F ( u , v ) )} ) ,$$

where F(u, v)=Re(F(u, v))+Im(F(u, v)). Thus, each vector k has phase which can be computed based on a location (e.g., u and v coordinates in the amplitude image) of that peak. The phase φ can range in value from −π to +π. Therefore, determining the precise value of phase φ necessitates determining the location of the peaks in the amplitude image precisely. Those values (e.g. angles) of the phases may be seen by phase image 1100. For example, points that are dark blue (e.g., point 1114) refers to a phase of −π, while points that are yellow refer to a phase of +π.

In some cases, due to symmetries of the original image (e.g., a periodicity in the pattern of features 602, 604, 620), phase angles may cancel each other out and therefore areas of phase image 1100 which contain data points may represent portions where there is asymmetry in the pattern(s). This asymmetry may be a result of overlay or other asymmetries arising from the lithographic printing process.

In terms of processing the 2D image signal, computing the phase may include performing the FFT to the original signal (e.g., the (x, y) pixel data), and extracting the real component of the transformed signal and the imaginary portion of the transformed signal. The amplitude of the vector k may then be given by computing |F(u, v)|=, {square root over (Re(F(u, v)²+Im(F(u, v)²)}, where F(u, v)=F(k). The value of the phase φ, for vector k, is computed via

$$φ = {tan}^{- 1} ( \frac{Im ( F ( u , v ) )}{Re ( F ( u , v ) )} ) .$$

In some embodiments, prior to analyzing phase image 1100, one or more image processing steps may be performed. For example, a thresholding filter may be applied to reduce noise in the image signal.

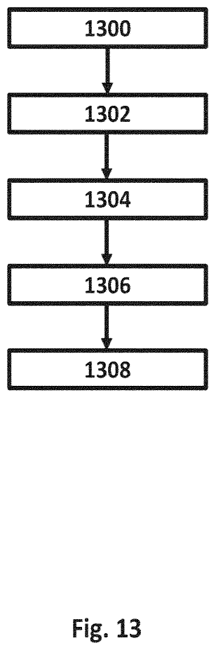

In some embodiments, the overlay error, represented by the vector ΔOV may be projected on the point of interest in the amplitude image, as seen, for example, by FIG. 12. The overlay error may be projected with respect to a reference overlay condition, such as overlay (OVL)=0. The overlay error is related to the extracted phase φ based on Equation (5):

$$Δ {φ}_{( nm )} = \frac{Δ {φ}_{( rad )}}{2 π \vert k \vert} = \hat{k} \cdot \overline{Δ OV} , \qquad ( 5 )$$

where Δφ_{(rad)} may be obtained using the method described below with respect to FIG. 13 and k is a unit vector in the direction of k.

With respect to FIG. 13, the method may begin at 1300, where image data representing an image of a patterned device (e.g., a substrate having stacked layers, where one or more of the stacked layers have been pattered using a lithographic patterning process) may be obtained. In some embodiments, the image data may be SEM image data representing an SEM image. For example, the image data (e.g., SEM image data) may be captured using a metrology system, such as that described above with respect to FIGS. 3-5. In some embodiments, one or more pre-processing steps may be performed to the image such as noise reduction, gray scale, cropping, scaling, windowing, etc. FIG. 6A depicts an example of an image of a patterned device.

At 1302, an amplitude image and a phase image may be generated based on a FFT being applied to the image data of the patterned device (e.g., substrate having stacked layers). The Fourier transform decomposes the spatial image of the patterned device into a collection of sinusoidal functions. The amplitude image may therefore depict an image of an intensity of each sinusoidal function at a particular frequency. As the intensity at each point corresponds to an amplitude of the sinusoidal function at the given 2D frequency, the amplitude of each point in Fourier space may be determined.

At 1304, the position of the peaks in the amplitude image may be fit. For example, a 2D sinusoidal function may be fit to the peaks. For example, a Gaussian function with a noise may be used. Based on the fit function, a position, in Fourier space, of each peak may be extracted. In some embodiments, the peaks may be stored with an associated position vector in Fourier space.

The overlay vector is calculated based on the k-vector, which extends from the origin in Fourier space to a point of interest in Fourier space. For example, as seen in FIG. 12, the vector k originates from a point p1 and extends to a point p2. The vector may be represented by the 2D frequency values of the position in Fourier space. Thus, the vector k may originate at point p1, having frequency coordinate u1, v1 (e.g., u1=0, v1=0) and may extend to point p2, having frequency coordinates u2, v2 (e.g., u2=u, v2=v). Each peak's corresponding coordinates in Fourier space can then be stored (e.g., {p1: u1, v1}, {p2: u2, v2}). In some embodiments, multiple sets of peaks may be fit to the amplitudes of amplitude image 900. Each set of peaks may correspond to features of a layer of the patterned device. For example, a first set of peaks may be fit to features on a first layer of a patterned device and a second set of peaks may be fit to features on a second layer of the patterned device. Based on whether the peaks were fit to the first set of peaks or the second set of peaks may be used to determine which peaks refer to the features in an “upper” layer or the features in a “lower” layer.

At 1306, a phase can be extracted from the phase image (e.g., phase image 1100) for a given peak. In some embodiments, a phase may be extracted from peaks representing the features on a “lower” layer of the imaged substrate (e.g., patterned device including stacked layers). In some cases, the phase may be extracted from the peaks representing the features on an “upper” layer of the imaged substrate. In some embodiments, the phase associated with each peak (or some of the peaks) may be stored in association to the frequency position in Fourier space (e.g., {p1: u1, v1, φ1}, {p2: u2, v2, φ2}). The phase may be computed via

$$φ = {tan}^{- 1} ( \frac{Im ( F ( u , v ) )}{Re ( F ( u , v ) )} ) ,$$

where F(u, v)=Re(F(u, v))+Im(F(u, v)).

To achieve sufficient accuracy, the phase extraction may include performing an interpolation of nearby pixels in the phase image. In some embodiments, u, and v are fractional coordinates. The interpolated pixels may be near phase wrapping boundaries (e.g., where a phase jumps from a value near+π to a value near −π). A phase unwrapping algorithm may be applied to correctly interpolate the phase.

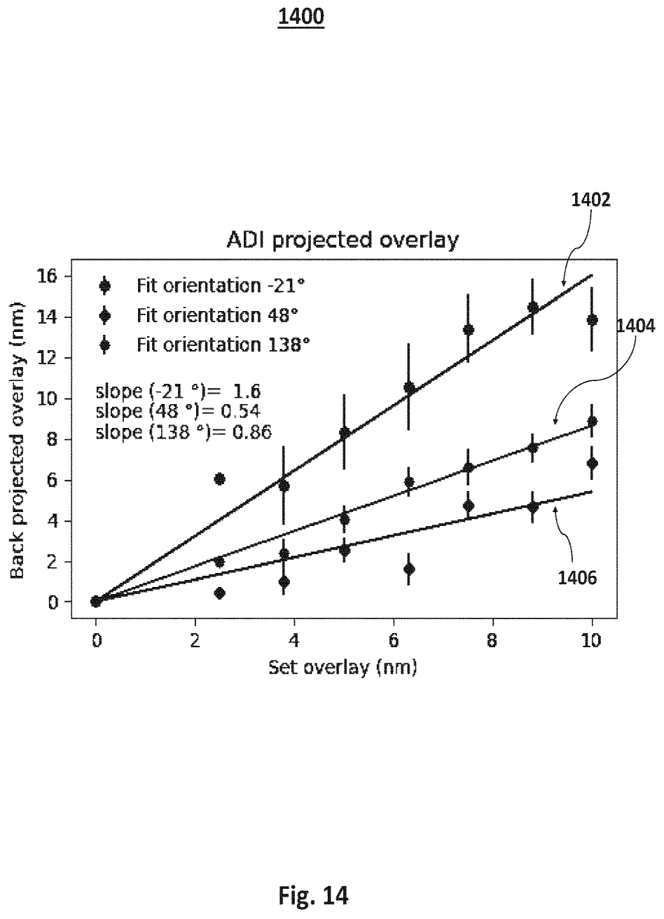

At 1308, the extracted phase may be translated into an overlay value. The overlay may be related to the extracted phase via Equation (5). Simulations further show that a calibration (or sensitivity constant) may be needed to improve accuracy of the overlay computation. The calibrated version of Equation (6) is listed below:

$$Δ {φ}_{( nm )} = \frac{Δ {φ}_{( rad )}}{2 π \vert k \vert} = {α}_{i , j , x / y} \hat{k} \cdot \overline{Δ OV} , \qquad ( 6 )$$

where α_{i,j, x/y} is a calibration constant to be computed using a calibration procedure, as described below. The indices i, j refer to the spot of interest indices and the x/y indices refer to the x/y overlay components. As an example, graph 1400 of FIG. 14 illustrates ΔOV assuming a calibration constant of unity (which reduces Equation (6) to be Equation (5)).

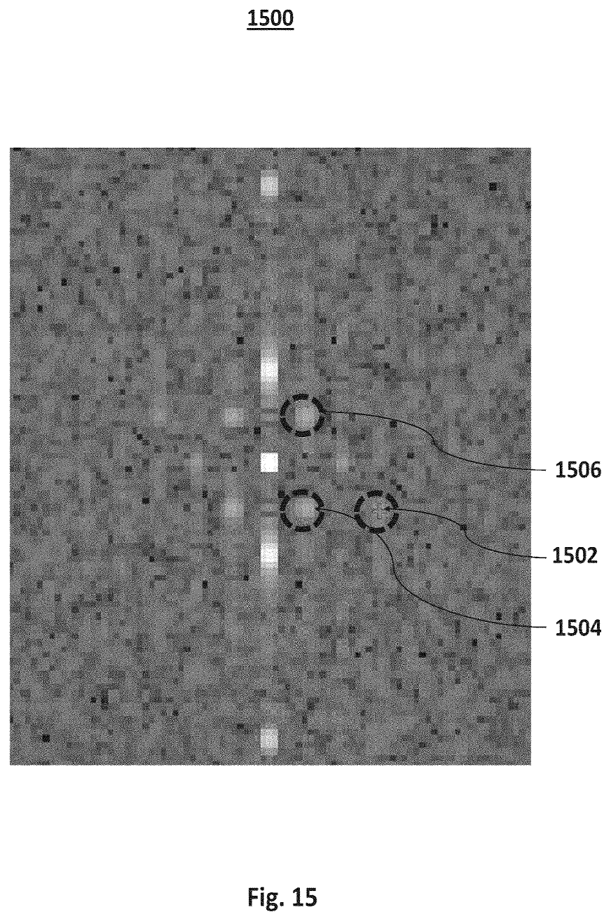

To perform the calibration, a plurality of images (e.g., SEM images) of the patterned device may be obtained. The images may be based on a simulation of a particular patterned device, or the images may be images of a physically patterned device. As an example, graph 1400 illustrates three (3) traces: trace 1402, trace 1404, and trace 1406. Each trace is associated with a k-vector orientation. For example, trace 1402 is associated with a k-vector orientation of −21 degrees, trace 1404 is associated with a k-vector orientation of 48 degrees, and trace 1406 is associated with a k-vector orientation of 138 degrees. As an example, with reference to image 1500 of FIG. 15, the k-vector orientation of −21 degrees refers to point 1502 in image 1500, the k-vector orientation of 48 degrees refers to point 1504, and the k-vector orientation 138 refers to the point 1506. Referring back to FIG. 14, the x and y components of the overlay can be computed, using Equation (5), for each peak (e.g., k-vector orientations −21 degrees, 48 degrees, 138 degrees) for each of a plurality of images of the patterned device. These points are plotted in graph 1400. For each collection of points corresponding to a given k-vector orientation, a linear function can be fit to the data points to obtain a calibration factor for the overlay computation. For example, the calibration factor for the phase angle −21 degrees should be 1.6, whereas the calibration factor for the phase angle 48 degrees and 138 degrees should be 0.54 and 0.86, respectively. In some embodiments, a higher order model may be used to relate phase to overlay.

In some embodiments the process of extracting phase from the phase image may involve an interpolation technique to interpolate the phase values on the phase image grid, to the (sub-pixel accurate) peak location obtained by fitting the peak location(s) on the amplitude image. Some embodiments may use linear, nearest neighbor or bicubic interpolation. Other embodiments may also include 1D or 2D phase unwrapping technique to results in more accurate interpolation values for phase.

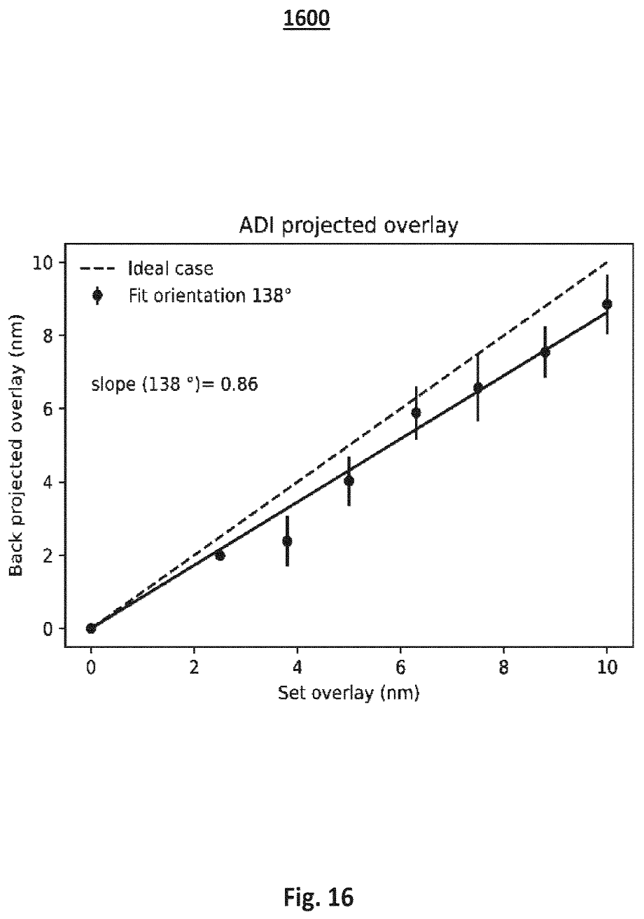

The effect of the calibration has can be seen, for example, with respect to FIG. 16. In FIG. 16, graph 1600 depicts an example of data points computed for a phase of 138 degrees. The slope, for these data points, is 0.86. However, the dashed line depicts what the fit data points would behave like if the slope was ideal (e.g., slope=1.0).

In some embodiments, the relationship between phase and overlay may be estimated using one or more machine learning models. For example, a machine learning model may be trained to predict an overlay between features (e.g., features on different layers of a stack) based on a phase. The machine learning techniques that can be used in the systems described herein may include, but are not limited to (which is not to suggest that any other list is limiting), any of the following: Ordinary Least Squares Regression (OLSR), Linear Regression, Logistic Regression, Stepwise Regression, Multivariate Adaptive Regression Splines (MARS), Locally Estimated Scatterplot Smoothing (LOESS), Instance-based Algorithms, k-Nearest Neighbor (KNN), Learning Vector Quantization (LVQ), Self-Organizing Map (SOM), Locally Weighted Learning (LWL), Regularization Algorithms, Ridge Regression, Least Absolute Shrinkage and Selection Operator (LASSO), Elastic Net, Least-Angle Regression (LARS), Decision Tree Algorithms, Classification and Regression Tree (CART), Iterative Dichotomizer 3 (ID3), C4.5 and C5.0 (different versions of a powerful approach), Chi-squared Automatic Interaction Detection (CHAID), Decision Stump, M5, Conditional Decision Trees, Naive Bayes, Gaussian Naive Bayes, Causality Networks (CN), Multinomial Naive Bayes, Averaged One-Dependence Estimators (AODE), Bayesian Belief Network (BBN), Bayesian Network (BN), k-Means, k-Medians, K-cluster, Expectation Maximization (EM), Hierarchical Clustering, Association Rule Learning Algorithms, A-priori algorithm, Eclat algorithm, Artificial Neural Network Algorithms, Perceptron, Back-Propagation, Hopfield Network, Radial Basis Function Network (RBFN), Deep Learning Algorithms, Deep Boltzmann Machine (DBM), Deep Belief Networks (DBN), Convolutional Neural Network (CNN), Deep Metric Learning, Stacked Auto-Encoders, Dimensionality Reduction Algorithms, Principal Component Analysis (PCA), Principal Component Regression (PCR), Partial Least Squares Regression (PLSR), Collaborative Filtering (CF), Latent Affinity Matching (LAM), Cerebri Value Computation (CVC), Multidimensional Scaling (MDS), Projection Pursuit, Linear Discriminant Analysis (LDA), Mixture Discriminant Analysis (MDA), Quadratic Discriminant Analysis (QDA), Flexible Discriminant Analysis (FDA), Ensemble Algorithms, Boosting, Bootstrapped Aggregation (Bagging), AdaBoost, Stacked Generalization (blending), Gradient Boosting Machines (GBM), Gradient Boosted Regression Trees (GBRT), Random Forest, Computational intelligence (evolutionary algorithms, etc.), Computer Vision (CV), Natural Language Processing (NLP), Recommender Systems, Reinforcement Learning, Graphical Models, or separable convolutions (e.g., depth-separable convolutions, spatial separable convolutions).

In some embodiments, the machine learning model may be trained based on training data formed of a plurality of SEM images. Each of the SEM images may depict a patterned device having features on a first, lower, layer and a second, upper layer. The different images may depict similar patterns or different patterns, and the extent of the overlay may vary across the various images. In some embodiments, the overlay may be a known value (either pre-programmed or pre-set during the fabrication process) or a measured value (e.g., using one or more metrology processes).

In some embodiments, a FFT may be applied to the SEM images. For each SEM image, captured in image space, the FFT may generate an amplitude image and a phase image representing the SEM image in Fourier space. Using the method described above with respect to FIG. 12, the obtained amplitude image may be fit to determine a peak position, in Fourier space, for each peak, which represents a feature in image space. The peaks corresponding to the features on the “upper” layer and the peaks corresponding to the features on the “lower” layer may be identified, and used to determine a phase angle representing a given point in the amplitude image corresponding to a peak of a feature (e.g., a feature from a lower layer). The phase may then be used to compute an overlay or overlay error.

The machine learning model may be trained during a training phase and validated to ensure accuracy. Upon training and validation being completed, the trained model may be deployed and used to compute an overlay between features of stacked layers based on an input phase.

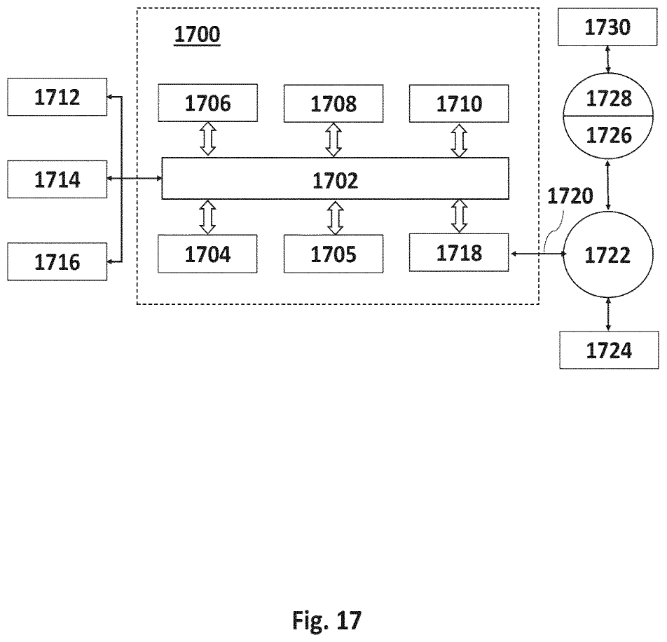

Referring to FIG. 17, a computer system 1700 is shown. The computer system 1700 includes a bus 1702 or other communication mechanism for communicating information, and a processor 1704 (or multiple processors 1704 and 1705) coupled with bus 1702 for processing information. Computer system 1700 also includes a main memory 1706, such as a random access memory (RAM) or other dynamic storage device, coupled to bus 1702 for storing information and instructions to be executed by processor 1704. Main memory 1706 also may be used for storing temporary variables or other intermediate information during execution of instructions to be executed by processor 1704. Computer system 1700 further includes a read only memory (ROM) 1708 or other static storage device coupled to bus 1702 for storing static information and instructions for processor 1704. A storage device 1710, such as a magnetic disk or optical disk, is provided and coupled to bus 1702 for storing information and instructions.

Computer system 1700 may be coupled via bus 1702 to a display 1712, such as a cathode ray tube (CRT) or flat panel or touch panel display for displaying information to a computer user. An input device 1714, including alphanumeric and other keys, is coupled to bus 1702 for communicating information and command selections to processor 1704. Another type of user input device is cursor control 1716, such as a mouse, a trackball, or cursor direction keys for communicating direction information and command selections to processor 1704 and for controlling cursor movement on display 1712. This input device typically has two degrees of freedom in two axes, a first axis (e.g., x) and a second axis (e.g., y), that allows the device to specify positions in a plane. A touch panel (screen) display may also be used as an input device.

The computer system 1700 may be suitable to function as a processing unit herein in response to processor 1704 executing one or more sequences of one or more instructions contained in main memory 1706. Such instructions may be read into main memory 1706 from another computer-readable medium, such as storage device 1710. Execution of the sequences of instructions contained in main memory 1706 causes processor 1704 to perform a process described herein. One or more processors in a multi-processing arrangement may also be employed to execute the sequences of instructions contained in main memory 1706. In alternative embodiments, hard-wired circuitry may be used in place of or in combination with software instructions. Thus, embodiments are not limited to any specific combination of hardware circuitry and software.

The term “computer-readable medium” as used herein refers to any medium that participates in providing instructions to processor 1704 for execution. Such a medium may take many forms, including but not limited to, non-volatile media, volatile media, and transmission media. Non-volatile media include, for example, optical or magnetic disks, such as storage device 1710. Volatile media include dynamic memory, such as main memory 1706. Transmission media include coaxial cables, copper wire and fiber optics, including the wires that comprise bus 1702. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1704 for execution. For example, the instructions may initially be borne on a magnetic disk of a remote computer. The remote computer can load the instructions into its dynamic memory and send the instructions over a telephone line using a modem. A modem local to computer system 1700 can receive the data on the telephone line and use an infrared transmitter to convert the data to an infrared signal. An infrared detector coupled to bus 1702 can receive the data carried in the infrared signal and place the data on bus 1702. Bus 1702 carries the data to main memory 1706, from which processor 1704 retrieves and executes the instructions. The instructions received by main memory 1706 may optionally be stored on storage device 1710 either before or after execution by processor 1704.

Computer system 1700 may also include a communication interface 1718 coupled to bus 1702. Communication interface 1718 provides a two-way data communication coupling to a network link 1720 that is connected to a local network 1722. For example, communication interface 1718 may be an integrated services digital network (ISDN) card or a modem to provide a data communication connection to a corresponding type of telephone line. As another example, communication interface 1718 may be a local area network (LAN) card to provide a data communication connection to a compatible LAN. Wireless links may also be implemented. In any such implementation, communication interface 1718 sends and receives electrical, electromagnetic or optical signals that carry digital data streams representing various types of information.

Network link 1720 typically provides data communication through one or more networks to other data devices. For example, network link 1720 may provide a connection through local network 1722 to a host computer 1724 or to data equipment operated by an Internet Service Provider (ISP) 1726. ISP 1726 in turn provides data communication services through the worldwide packet data communication network, now commonly referred to as the “Internet” 1728. Local network 1722 and Internet 1728 both use electrical, electromagnetic or optical signals that carry digital data streams. The signals through the various networks and the signals on network link 1720 and through communication interface 1718, which carry the digital data to and from computer system 1700, are exemplary forms of carrier waves transporting the information.

Computer system 1700 can send messages and receive data, including program code, through the network(s), network link 1720, and communication interface 1718. In the Internet example, a server 1730 might transmit a requested code for an application program through Internet 1728, ISP 1726, local network 1722 and communication interface 1718. In accordance with one or more embodiments, one such downloaded application provides for a method as disclosed herein, for example. The received code may be executed by processor 1704 as it is received, and/or stored in storage device 1710, or other non-volatile storage for later execution. In this manner, computer system 1700 may obtain application code in the form of a carrier wave.

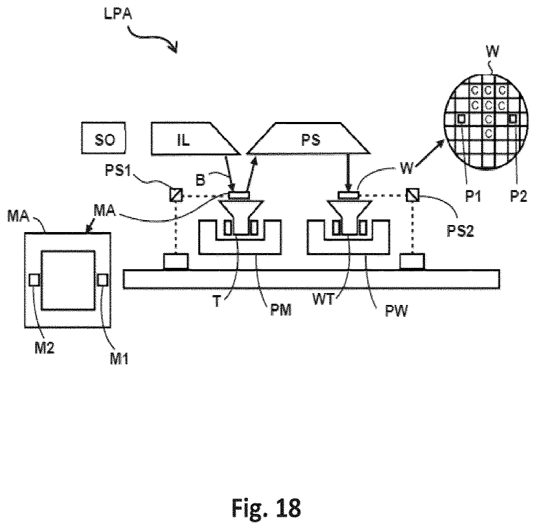

FIG. 18 is a schematic diagram of another lithographic projection apparatus (LPA) that may be used for, or facilitate one or more of the operations described herein. The LPA shown in FIG. 18 is similar to or the same as the apparatus shown in FIG. 1. LPA can include source collector module SO, illumination system (illuminator) IL configured to condition a radiation beam B (e.g. EUV radiation), patterning device table T, substrate table WT, and projection system PS. Patterning device table T can be constructed to support a patterning device (e.g. a mask or a reticle) MA and connected to a first positioner PM configured to accurately position the patterning device. Substrate table (e.g. a wafer table) WT can be constructed to hold a substrate (e.g. a resist coated wafer) W and connected to a second positioner PW configured to accurately position the substrate. Projection system (e.g. a reflective projection system) PS can be configured to project a pattern imparted to the radiation beam B by patterning device MA onto a target portion C (e.g. comprising one or more dies) of the substrate W.

As shown in this example, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 17), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer or inner radial extent (commonly referred to as c-outer and c-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held by patterning device table T, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder, or capacitive sensor), the substrate table WT can be moved accurately (e.g. to position different target portions C in the path of radiation beam B). Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the patterning device table T and the substrate table WT are kept essentially stationary, while an entire pattern imparted to the radiation beam is projected onto a target portion C at one time (e.g., a single static exposure). The substrate table WT is then shifted in the X or Y direction so that a different target portion C can be exposed. In scan mode, the patterning device table T and the substrate table WT are scanned synchronously while a pattern imparted to the radiation beam is projected onto target portion C (i.e. a single dynamic exposure). The velocity and direction of substrate table WT relative to the patterning device table T may be determined by the (de)magnification and image reversal characteristics of the projection system PS. In stationary mode, the patterning device table T is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

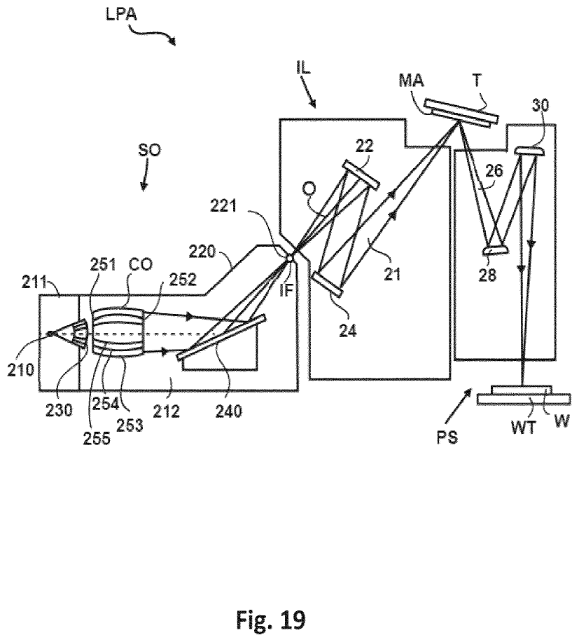

FIG. 19 is a more detailed view of the lithographic projection apparatus shown in FIG. 19 (or FIG. 1). As shown in FIG. 19, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 212 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the patterning device table T, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 19.

Collector optic CO, as illustrated in FIG. 19, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

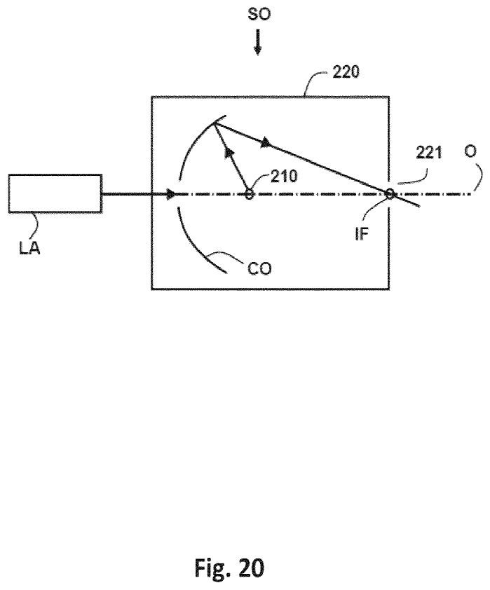

FIG. 20 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10″s of eV. The energetic radiation generated during de-excitation and recombination of these ions is emitted from the plasma, collected by a near normal incidence collector optic CO and focused onto the opening 221 in the enclosing structure 220.

An embodiment of the disclosure may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according to the machine readable instructions of one or more computer programs.

Although specific reference may be made in this text to the use of a metrology apparatus in the manufacture of ICs, it should be understood that the metrology apparatus and processes described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or one or more various other tools. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the disclosure in the context of optical lithography, it will be appreciated that the disclosure may be used in other applications, for example nanoimprint lithography, and where the context allows, is not limited to optical lithography. In the case of nanoimprint lithography, the patterning device is an imprint template or mold.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments. For example, determining enhanced MRC criteria may comprise its own separate embodiment, or it may be included with one or more other embodiments that also include performing the actual check, as described herein.

The descriptions above are intended to be illustrative, not limiting. Thus, it will be apparent to one skilled in the art that modifications may be made as described without departing from the scope of the claims set out below.

Further embodiments according to the invention are described in below numbered clauses:

1. A non-transitory computer-readable medium storing computer program instructions that when executed by a computer, cause the computer to perform operations comprising: obtaining image data of features on a substrate; analyzing the image data in Fourier space; determining an amplitude and a phase based on the analysis; and determining an overlay of the features based on the amplitude and the phase.
2. The non-transitory computer-readable medium of clause 1, wherein the features comprise first features on a first layer of the substrate and second features on a second layer of the substrate, the second layer being formed over the first layer.
3. The non-transitory computer-readable medium of clause 2, wherein the image data comprises an image of the substrate formed by scanning an electron beam in one or more directions.
4. The non-transitory computer-readable medium of any one of clauses 1-3, wherein the image data is captured via electron microscopy.
5. The non-transitory computer-readable medium of clause 4, wherein a scanning electron microscope (SEM) is used to perform the electron microscopy capturing an SEM image, wherein the image data comprises SEM image data representing the SEM image.
6. The non-transitory computer-readable medium of any one of clauses 1-5, wherein analyzing the image data in Fourier space comprises: generating, responsive to application of a fast Fourier Transform (FFT) to the image data, an amplitude image and a phase image, wherein the amplitude is determined based on the amplitude image and the phase is determined based on the phase image.
7. The non-transitory computer-readable medium of clause 6, wherein the image data comprises an image of the substrate, a first layer formed on the substrate, and a second layer formed on the first layer, the amplitude image depicting, in Fourier space, an amplitude of the features, the features being formed on at least one of the first layer or the second layer, and wherein determining the amplitude comprises: determining, from the features, based on the amplitude, a first set of features located on the first layer; and determining, from the features, based on the amplitude, a second set of features located on the second layer, wherein the overlay is determined based on the first set of features and the second set of features.
8. The non-transitory computer-readable medium of clause 7, wherein determining the phase comprises: determining, for each of the first set of features, based on the phase image, a respective phase of a corresponding first feature of the first set of features in Fourier space to obtain a set of phases, wherein the overlay is determined based on the set of phases.
9. The non-transitory computer-readable medium of any one of clauses 1-8, wherein the image data comprises an image of the substrate having first features on a first layer and second features on a second layer, wherein the second layer is formed on the first layer, wherein determining the overlay comprises: providing, as input, to a model, the phase; and obtaining, from the model, an estimated overlay between the first features and the second features.
10. The non-transitory computer-readable medium of clause 9, wherein the model is trained using a plurality of images of substrates comprising stacked features, wherein each image of the plurality of images includes metadata indicating an overlay of the stacked features, wherein each of the stacked features comprises a first set of features on a first layer of a respective substrate and a second set of features on a second layer of the respective substrate.
11. The non-transitory computer-readable medium of any one of clauses 1-10, wherein the image data comprises an image of a substrate comprising a first layer and a second layer formed on the first layer, analyzing the image data in Fourier space comprises: generating, responsive to application of a fast Fourier Transform (FFT) to the image data, an amplitude image and a phase image representing the image in Fourier space; assigning peaks in the amplitude image to the features, wherein each of the peaks are assigned to one of first features included in the first layer or second features included in the second layer, wherein a phase of each of the first features is interpolated based on a respective peak.
12. The non-transitory computer-readable medium of any one of clauses 1-11, wherein the image data is obtained by imaging the substrate using a metrology system.
13. A metrology system, comprising: a computing system configured to execute computer-program instructions to effectuate operations comprising: obtaining image data of features on a substrate; analyzing the image data in Fourier space; determining an amplitude and a phase based on the analysis; and determining an overlay based on the amplitude and the phase.
14. The metrology system of clause 13, wherein the image data comprises an image of the substrate, the substrate being patterned using a patterning process forming the features, the features comprising first features on a first layer of the substrate and second features on a second layer of the substrate, the second layer being formed over the first layer.
15. The metrology system of clause 14, wherein the image data comprises an image of the substrate formed by scanning an electron beam in one or more directions.
16. The metrology system of any one of clauses 13-15, wherein the image data is captured via electron microscopy.
17. The metrology system of clause 16, wherein a scanning electron microscope (SEM) is used to perform the electron microscopy capturing an SEM image, wherein the image data comprises SEM image data representing the SEM image.
18. The metrology system of any one of clauses 13-17, wherein analyzing the image data in Fourier space comprises: generating, responsive to application of a fast Fourier Transform (FFT) to the image data, an amplitude image and a phase image, wherein the amplitude is determined based on the amplitude image and the phase is determined based on the phase image.
19. The metrology system of clause 18, wherein the image data comprises an image the substrate, a first layer formed on the substrate, and a second layer formed on the first layer, the amplitude image depicting an amplitude, in Fourier space, of the features, wherein the features are formed on at least one of the first layer or the second layer, determining the amplitude comprises: determining, from the features, based on the amplitude, a first set of features located on the first layer; and determining, from the features, based on the amplitude, a second set of features located on the second layer, wherein the overlay is determined based on the first set of features and the second set of features.
20. The metrology system of clause 19, wherein determining the phase comprises: determining, for each of the first set of features, based on the phase image, a respective phase of a corresponding first feature of the first set of features in Fourier space to obtain a set of phases, wherein the overlay is determined based on the set of phases.
21. The metrology system of any one of clauses 13-20, wherein the features comprise first features formed on a first layer of the substrate and second features formed on a second layer of the substrate, wherein the second layer is formed on the first layer, determining the overlay comprises: providing, as input, to a model, the phase; and obtaining, from the model, an estimated overlay between an instance of the first features and an instance of the second features.
22. The metrology system of clause 21, wherein the model is trained using a plurality of images of substrates comprising stacked features, wherein each image of the plurality of images includes metadata indicating an overlay of the stacked features, wherein each of the stacked features comprises a first set of features on a first layer of a respective substrate and a second set of features on a second layer of the respective substrate.
23. The metrology system of any one of clauses 13-22, wherein the image data comprises an image of a substrate comprising a first layer and a second layer formed on the first layer, analyzing the image data in Fourier space comprises: generating, responsive to application of a fast Fourier Transform (FFT) to the image data, an amplitude image and a phase image representing the image in Fourier space; assigning peaks in the amplitude image to the features, wherein each of the peaks are assigned to one of first features included in the first layer or second features included in the second layer, wherein a phase of each of the first features is interpolated based on a respective peak.
24. A method implemented by one or more processors executing computer program instructions stored in memory, the method comprising: obtaining image data of features on a substrate; analyzing the image data in Fourier space; determining an amplitude and a phase based on the analysis; and determining an overlay based on the amplitude and the phase.
25. The method of clause 24, wherein the features comprise first features on a first layer of the substrate and second features on a second layer of the substrate, the second layer being formed over the first layer.
26. The method of clause 25, wherein the image data comprises an image of the substrate formed by scanning an electron beam in one or more directions.
27. The method of any one of clauses 24-26, wherein the image data is captured via electron microscopy.
28. The method of clause 27, wherein a scanning electron microscope (SEM) is used to perform the electron microscopy capturing an SEM image, wherein the image data comprises SEM image data representing the SEM image.
29. The method of any one of clauses 24-28, wherein analyzing the image data in Fourier space comprises: generating, responsive to application of a fast Fourier Transform (FFT) to the image data, an amplitude image and a phase image, wherein the amplitude is determined based on the amplitude image and the phase is determined based on the phase image.
30. The method of clause 29, wherein the image data comprises an image of the substrate, a first layer formed on the substrate, and a second layer formed on the first layer, the amplitude image depicting, in Fourier space, an amplitude of the features, the features being formed on at least one of the first layer or the second layer, and wherein determining the amplitude comprises: determining, from the features, based on the amplitude, a first set of features located on the first layer; and determining, from the features, based on the amplitude, a second set of features located on the second layer, wherein the overlay is determined based on the first set of features and the second set of features.
31. The method of clause 30, wherein determining the phase comprises: determining, for each of the first set of features, based on the phase image, a respective phase of a corresponding first feature of the first set of features in Fourier space to obtain a set of phases, wherein the overlay is determined based on the set of phases.
32. The method of any one of clauses 24-31, wherein the image data comprises an image of the substrate having first features on a first layer and second features on a second layer, wherein the second layer is formed on the first layer, wherein determining the overlay comprises: providing, as input, to a model, the phase; and obtaining, from the model, an estimated overlay between the first features and the second features.
33. The method of clause 32, wherein the model is trained using a plurality of images of substrates comprising stacked features, wherein each image of the plurality of images includes metadata indicating an overlay of the stacked features, wherein each of the stacked features comprises a first set of features on a first layer of a respective substrate and a second set of features on a second layer of the respective substrate.
34. The method of any one of clauses 24-33, wherein the image data comprises an image of a substrate comprising a first layer and a second layer formed on the first layer, analyzing the image data in Fourier space comprises: generating, responsive to application of a fast Fourier Transform (FFT) to the image data, an amplitude image and a phase image representing the image in Fourier space; assigning peaks in the amplitude image to the features, wherein each of the peaks are assigned to one of first features included in the first layer or second features included in the second layer, wherein a phase of each of the first features is interpolated based on a respective peak.
35. The method of any one of clauses 24-34, wherein the image data is obtained by imaging the substrate using a metrology system.
36. A computer program product comprising a computer non-transitory readable medium having instructions recorded thereon, the instructions when executed by a computer implementing the method of any of clauses 24-35.
37. A system comprising: a hardware processor system; and a non-transitory computer readable storage medium configured to store machine-readable instructions, wherein when executed, the machine-readable instructions cause the hardware processor system to perform a method of any of clauses 24-35.
38. A metrology apparatus for measuring an object of a patterning process, the metrology apparatus configured to perform the method of any of clauses 24-35.
39. A system comprising: a metrology apparatus configured to provide a beam of radiation onto an object surface and to detect radiation redirected by the structure on the object surface; and the computer program product of clause 36.
40. The system of clause 39, further comprising: a lithographic apparatus comprising a support structure configured to hold a patterning device to modulate a radiation beam and a projection optical system arranged to project the modulated radiation beam onto a radiation-sensitive substrate, wherein the object is the substrate and the lithographic apparatus is configured to control a setting of the lithographic apparatus based on information obtained using the metrology apparatus and the computer program product.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

References herein to crossing or passing a threshold may include something having a value lower than a specific value or lower than or equal to a specific value, something having a value higher than a specific value or higher than or equal to a specific value, something being ranked higher or lower than something else (through e.g., sorting) based on, e.g., a parameter, etc.

References herein to correcting or corrections of an error include eliminating the error or reducing the error to within a tolerance range.

The term “optimizing” and “optimization” as used herein refers to or means adjusting a lithographic apparatus, a patterning process, etc. such that results and/or processes of lithography or patterning processing have more a desirable characteristic, such as higher accuracy of projection of a design layout on a substrate, a larger process window, etc. Thus, the term “optimizing” and “optimization” as used herein refers to or means a process that identifies one or more values for one or more variables that provide an improvement, e.g. a local optimum, in at least one relevant metric, compared to an initial set of one or more values for those one or more variables. “Optimum” and other related terms should be construed accordingly. In an embodiment, optimization steps can be applied iteratively to provide further improvements in one or more metrics.

In an optimization process of a system, a figure of merit of the system or process can be represented as a cost function. The optimization process boils down to a process of finding a set of parameters (design variables) of the system or process that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system or process with respect to the intended values (e.g., ideal values) of these characteristics; the cost function can also be the maximum of these deviations (i.e., worst deviation). The term “evaluation points” herein should be interpreted broadly to include any characteristics of the system or process. The design variables of the system can be confined to finite ranges and/or be interdependent due to practicalities of implementations of the system or process. In the case of a lithographic apparatus or patterning process, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

While specific embodiments of the disclosure have been described above, it will be appreciated that the disclosure may be practiced otherwise than as described. For example, the disclosure may take the form of a computer program containing one or more sequences of machine-readable instructions describing a method as disclosed above, or a data storage medium (e.g. semiconductor memory, magnetic or optical disk) having such a computer program stored therein.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, applicants have grouped these inventions into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such inventions or all aspects of such inventions.

It should be understood that the description and the drawings are not intended to limit the invention to the particular form disclosed, but to the contrary, the intention is to cover all modifications, equivalents, and alternatives falling within the spirit and scope of the present invention as defined by the appended claims.

Modifications and alternative embodiments of various aspects of the invention will be apparent to those skilled in the art in view of this description. Accordingly, this description and the drawings are to be construed as illustrative only and are for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description of the invention. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

The descriptions above are intended to be illustrative, not limiting. Thus, it will be apparent to one skilled in the art that modifications may be made to the disclosure as described without departing from the scope of the claims set out below.

1. A non-transitory computer-readable medium storing computer program instructions that, when executed by a computer system, are configured to cause the computer system to at least:
obtain image data of features on a substrate;
analyze the image data in Fourier space;
determine an amplitude and a phase based on the analysis; and
determine an overlay of the features based on the amplitude and the phase.

2. The non-transitory computer-readable medium of claim 1, wherein the features comprise first features on a first layer of the substrate and second features on a second layer of the substrate, the second layer being formed over the first layer.

3. The non-transitory computer-readable medium of claim 2, wherein the image data comprises an image of the substrate formed by scanning an electron beam in one or more directions.

4. The non-transitory computer-readable medium of claim 1, wherein the image data is captured via electron microscopy.

5. The non-transitory computer-readable medium of claim 4, wherein a scanning electron microscope (SEM) is used to perform the electron microscopy to capture a SEM image, wherein the image data comprises SEM image data representing the SEM image.

6. The non-transitory computer-readable medium of claim 1, wherein the instructions configured to cause the computer system to analyze the image data in Fourier space are further configured to cause the computer system to generate, responsive to application of a fast Fourier Transform (FFT) to the image data, an amplitude image and a phase image, wherein the amplitude is determined based on the amplitude image and the phase is determined based on the phase image.

7. The non-transitory computer-readable medium of claim 6, wherein the image data comprises an image of the substrate, of a first layer formed on the substrate, and of a second layer formed on the first layer, wherein the amplitude image depicts, in Fourier space, an amplitude of the features, the features being formed on the first layer and/or the second layer, and wherein the instructions configured to cause the computer system to determine the amplitude are further configured to cause the computer system to:
determine, from the features and based on the amplitude, a first set of features located on the first layer; and
determine, from the features and based on the amplitude, a second set of features located on the second layer, wherein the overlay is determined based on the first set of features and the second set of features.

8. The non-transitory computer-readable medium of claim 7, wherein the instructions configured to cause the computer system to determine the phase are further configured to cause the computer system to determine, for each of the first set of features and based on the phase image, a respective phase of a corresponding first feature of the first set of features in Fourier space to obtain a set of phases, wherein the overlay is determined based on the set of phases.

9. The non-transitory computer-readable medium of claim 1, wherein the image data comprises an image of the substrate having first features on a first layer and second features on a second layer, wherein the second layer is formed on the first layer, and wherein the instructions configured to cause the computer system to determine the overlay are further configured to cause the computer system to:
provide, as input, to a model, the phase; and
obtain, from the model, an estimated overlay between the first features and the second features.

10. The non-transitory computer-readable medium of claim 9, wherein the model is trained using a plurality of images of substrates comprising stacked features, wherein each image of the plurality of images includes metadata indicating an overlay of the stacked features, and wherein each of the stacked features comprises a first set of features on a first layer of a respective substrate and a second set of features on a second layer of the respective substrate.

11. The non-transitory computer-readable medium of claim 1, wherein the image data comprises an image of a substrate comprising a first layer and a second layer formed on the first layer, and wherein the instructions configured to cause the computer system to analyze the image data in Fourier space are further configured to cause the computer system to:
generate, responsive to application of a fast Fourier Transform (FFT) to the image data, an amplitude image and a phase image representing the image in Fourier space; and
assign peaks in the amplitude image to the features, wherein each of the peaks are assigned to one of first features included in the first layer or second features included in the second layer, wherein a phase of each of the first features is interpolated based on a respective peak.

12. The non-transitory computer-readable medium of claim 1, wherein the image data is obtained by imaging the substrate using a metrology system.

13. A metrology system, comprising:
a computing system configured to execute computer-program instructions configured to cause the computing system to at least:
obtain image data of features on a substrate;
analyze the image data in Fourier space;
determine an amplitude and a phase based on the analysis; and
determine an overlay based on the amplitude and the phase.

14. The metrology system of claim 13, wherein the image data comprises an image of the substrate, the substrate being patterned using a patterning process forming the features, the features comprising first features on a first layer of the substrate and second features on a second layer of the substrate, the second layer being formed over the first layer.

15. A method comprising:
obtaining image data of features on a substrate;
analyzing, by one or more processors, the image data in Fourier space;
determining an amplitude and a phase based on the analysis; and
determining an overlay based on the amplitude and the phase.

16. The method of claim 15, wherein the features comprise first features on a first layer of the substrate and second features on a second layer of the substrate, the second layer being formed over the first layer.

17. The method of claim 16, wherein the image data comprises an image of the substrate formed by scanning an electron beam in one or more directions.

18. The method of claim 15, wherein the image data is captured via electron microscopy.

19. The method of claim 18, wherein a scanning electron microscope (SEM) is used to perform the electron microscopy to capture a SEM image, wherein the image data comprises SEM image data representing the SEM image.

20. The method of claim 15, wherein analyzing the image data in Fourier space comprises generating, responsive to application of a fast Fourier Transform (FFT) to the image data, an amplitude image and a phase image, wherein the amplitude is determined based on the amplitude image and the phase is determined based on the phase image.
